(19) United States
(12) Patent Application Publication
(10) Pub. No.: US 2025/0366334 A1
(43) Pub. Date: Nov. 27, 2025

(54) DISPLAY DEVICE

(71) Applicant: Samsung Display Co., LTD., Yongin-si (KR)

(72) Inventor: Jong Hyun CHOI, Yongin-si (KR)

(21) Appl. No.: 19/037,683

(22) Filed: Jan. 27, 2025

(30) Foreign Application Priority Data
May 24, 2024 (KR) 10-2024-0067819

(51) Int. Cl. H10K 59/131

(52) U.S. Cl. CPC H10K 59/1315

(57) ABSTRACT

A display device includes a substrate, a circuit layer and an element layer, where the circuit layer includes emissive pixel driving units, data lines, first auxiliary lines, second auxiliary lines, and gate initialization voltage lines. The emissive pixel driving units include a first emissive pixel driving unit and a second emissive pixel driving unit, which are disposed adjacent to each other in the second direction. A first gate initialization voltage line among the gate initialization voltage lines which overlaps with a boundary between the first and second emissive pixel driving units. At least a portion of the first emissive pixel driving unit is symmetrical with at least a portion of the second emissive pixel driving unit based on the boundary between the first and second emissive pixel driving units. A portion of at least one of the first auxiliary lines overlaps with the first gate initialization voltage line.

This application claims priority to Korean Patent Application No. 10-2024-0067819, filed on May 24, 2024, and all the benefits accruing therefrom under 35 U.S.C. § 119, the content of which in its entirety is herein incorporated by reference.

### BACKGROUND

### 1. Field

The present invention relates to a display device.

### 2. Description of the Related Art

As the information society develops, the demand for display devices to show images is increasing in various forms. For example, display devices are applied to various electronic devices such as smartphones, digital cameras, laptop computers, navigations, and smart televisions.

The display devices may be flat display devices such as a liquid crystal display (LCD) device, a field emission display (FED) device, or a light-emitting display device. Here, the light-emitting display device may include an organic light-emitting display device that includes organic light-emitting elements, an inorganic light-emitting display device that includes inorganic light-emitting elements such as an inorganic semiconductor, and a micro-light-emitting display device that includes micro-light-emitting elements.

The organic light-emitting display device displays an image using light-emitting elements each containing a light-emitting layer of an organic light-emitting material. Since the organic light-emitting display device implements image display using self-luminous elements, it can have relatively superior performance in power consumption, response speed, luminous efficiency, brightness, and wide viewing angle compared to other display devices.

One surface of a display device may include a display area where an image is displayed and a non-display area around the display area. In the display area, emission areas that emit light with respective brightness and color may be arranged.

### SUMMARY

In an embodiment, a display device may include light-emitting elements, which are disposed in the respective emission areas, and emissive pixel driving units, which are electrically connected to the light-emitting elements. The emissive pixel driving units may supply a driving current to the respective light-emitting elements.

In an embodiment, each of the emissive pixel driving units may include a first transistor, which generates the driving current, a second transistor, which is electrically connected between the first transistor and a data line delivering a data signal, and additional transistors for selective electrical connection, initialization, or reset of certain nodes.

It may be difficult to reduce the width of the emissive pixel driving units, potentially limiting the high-resolution capability of the display device.

Aspects of the invention provide a display device that can reduce the width of each emissive pixel driving unit while maintaining its transistors, thereby achieving high resolution.

However, aspects of the invention are not restricted to those set forth herein. The above and other aspects of the invention will become more apparent to one of ordinary skill in the art to which the invention pertains by referencing the detailed description of the present disclosure given below.

According to an embodiment, there is provided a display device which includes a substrate including a display area, where emission areas are arranged, and a non-emission area, which is disposed around the display area, a circuit layer disposed on the substrate and an element layer disposed on the circuit layer and including light-emitting elements, which are disposed in the emission regions, respectively. The circuit layer includes emissive pixel driving units, which are electrically connected to the light-emitting elements, respectively, and which are arranged to be directed parallel to one another in first and second directions that intersect each other. The circuit layer further includes data lines, which extend in the second direction and which deliver data signals to the emissive pixel driving units, first auxiliary lines, which extend in the first direction, second auxiliary lines, which extend in the second direction and which are disposed adjacent to the data lines and gate initialization voltage lines, which deliver a gate initialization voltage to the emissive pixel driving units. The emissive pixel driving units include a first emissive pixel driving unit and a second emissive pixel driving unit, which are disposed adjacent to each other in the second direction. A first gate initialization voltage line among the gate initialization voltage lines overlaps with a boundary between the first and second emissive pixel driving units. At least a portion of the first emissive pixel driving unit is symmetrical with at least a portion of the second emissive pixel driving unit based on the boundary between the first and second emissive pixel driving units. A portion of at least one of the first auxiliary lines overlaps with the first gate initialization voltage line.

In an embodiment, the circuit layer further includes a first semiconductor layer, which is disposed on the substrate, a first gate insulating layer, which covers the first semiconductor layer, a first gate conductive layer, which is disposed on the first gate insulating layer, a second gate insulating layer, which covers the first gate conductive layer, a second gate conductive layer, which is disposed on the second gate insulating layer, a first interlayer insulating layer, which covers the second gate conductive layer, a second semiconductor layer, which is disposed on the first interlayer insulating layer, a third gate insulating layer, which covers the second semiconductor layer, a third gate conductive layer, which is disposed on the third gate insulating layer and a second interlayer insulating layer, which covers the third gate conductive layer. The first and second semiconductor layers of the first emissive pixel driving unit are symmetrical with the first and second semiconductor layers of the second emissive pixel driving unit based on the boundary between the first and second emissive pixel driving units.

In an embodiment, the emissive pixel driving units further include a third emissive pixel driving unit, which is disposed adjacent to the first emissive pixel driving unit in the first direction and a fourth emissive pixel driving unit, which is disposed adjacent to the second emissive pixel driving unit in the first direction. The first gate initialization voltage line further overlaps with a boundary between the third and fourth emissive pixel driving units. The first and second semiconductor layers of the third emissive pixel driving unit are symmetrical with the first and second semiconductor layers of the fourth emissive pixel driving unit based on the boundary between the third and fourth emissive pixel driving units.

In an embodiment, a portion of the first gate initialization voltage line intersects a junction among the first, second, third, and fourth emissive pixel driving units. A portion of at least one of the first auxiliary lines overlaps with a portion of the first gate initialization voltage line.

In an embodiment, the emissive pixel driving units further include a fifth emissive pixel driving unit, which is disposed adjacent to the second emissive pixel driving unit in the second direction and a sixth emissive pixel driving unit, which is disposed adjacent to the fifth emissive pixel driving unit in the second direction. A second gate initialization voltage line among the gate initialization voltage lines overlaps with a boundary between the fifth and sixth emissive pixel driving units. The first and second semiconductor layers of the fifth emissive pixel driving unit are symmetrical with the first and second semiconductor layers of the sixth emissive pixel driving unit based on the boundary between the fifth and sixth emissive pixel driving units. A portion of at least one other of the first auxiliary lines overlaps with the second gate initialization voltage line.

In an embodiment, the first gate initialization voltage line overlaps with a portion of one of the first auxiliary lines. The second gate initialization voltage line overlaps with a portion of another one of first auxiliary line.

In an embodiment, the circuit layer further includes bias voltage lines, which deliver a bias voltage to the emissive pixel driving units, and anode initialization voltage lines, which deliver an anode initialization voltage to the emissive pixel driving units. One of the bias voltage lines and one of the anode initialization voltage lines are disposed adjacent to a boundary between the second and fifth emissive pixel driving units. A portion of another one of the first auxiliary lines overlaps with a portion of the one bias voltage line or a portion of the one anode initialization voltage line.

In an embodiment, the display device further includes a display driving circuit, which supplies data signals to the data lines. The circuit layer further includes data supply lines, which are disposed in the non-emission area and electrically connected between the data lines and the display driving circuit. A bypass area on one side of the display area includes a bypass middle area, a first bypass side area, which is disposed adjacent to the non-emission area and which is directed parallel to the bypass middle area in the first direction, and a second bypass side area, which is disposed between the bypass middle area and the first bypass side area. The data supply lines extend into the bypass middle area and the second bypass side area. The data lines include first data lines, which are disposed in the first bypass side area, and second data lines, which are disposed in the second bypass side area. The first auxiliary lines include first bypass auxiliary lines, which are electrically connected to the first data lines, and first transmission auxiliary lines, which are the other first auxiliary lines that are not the first bypass auxiliary lines. The second auxiliary lines include second bypass auxiliary lines, which are electrically connected to the first bypass auxiliary lines and which are disposed adjacent to the second data lines, and second transmission auxiliary lines, which are the other second auxiliary lines that are not the second bypass auxiliary lines. The data supply lines include first data supply lines and second data supply lines. the first data supply lines deliver data signals to the first data lines and are electrically connected to the first data lines through the first bypass auxiliary lines and the second bypass auxiliary lines. The second data supply lines deliver data signals to the second data lines and are directly electrically connected to the second data lines.

In an embodiment, the circuit layer further includes a first power supply line, which delivers a first power supply to the emissive pixel driving units. The light-emitting elements are electrically connected between the emissive pixel driving units and a second power supply. At least some of the first transmission auxiliary lines and at least some of the second transmission auxiliary lines deliver the second power supply.

In an embodiment, the first gate initialization voltage line overlaps with portions of two of the first bypass auxiliary lines among the first auxiliary lines.

In an embodiment, the emissive pixel driving units further include a seventh emissive pixel driving unit and an eight emissive pixel driving unit, which are disposed adjacent to each other in the second direction, a ninth emissive pixel driving unit, which is disposed adjacent to the seventh emissive pixel driving unit in the first direction and a tenth emissive pixel driving unit, which is disposed adjacent to the eighth emissive pixel driving unit in the first direction. A third gate initialization voltage line among the gate initialization voltage lines overlaps with a boundary between the seventh and eighth emissive pixel driving units and with a boundary between the ninth and tenth emissive pixel driving units. A portion of one of the first transmission auxiliary lines overlaps with the third gate initialization voltage line.

In an embodiment, portions of the two first bypass auxiliary lines are disposed adjacent to the junction among the first, second, third, and fourth emissive pixel driving units and are arranged with a first width. A portion of the one first transmission auxiliary line is disposed adjacent to a junction among the seventh, eighth, ninth, and tenth emissive pixel driving units and is arranged with a second width that is greater than the first width.

In an embodiment, the element layer includes anode electrodes, which are disposed in the emission areas, a pixel-defining layer, which is disposed in the non-emission area between the emission areas and covers edges of the anode electrodes, light-emitting layers, which are disposed on the anode electrodes and a cathode electrode, which is disposed on the pixel-defining layer and the light-emitting layers. Portions of the two first bypass auxiliary lines overlap with one of the anode electrodes and a portion of the one first transmission auxiliary line overlaps with another one of the anode electrodes.

In an embodiment, one of the emissive pixel driving units includes a first transistor, which is electrically connected between a first node and a second node, a pixel capacitor, which is electrically connected between a third node and a first power supply line delivering the first power supply, a second transistor, which is electrically connected between one of the data lines and the first node, a third transistor, which is electrically connected between the second and third nodes, a fourth transistor, which is electrically connected between one of the gate initialization voltage lines and the third node, a fifth transistor, which is electrically connected between the first power supply line and the first node, a sixth transistor, which is electrically connected between the second node and a fourth node, a seventh transistor, which is electrically connected between the first node and an anode initialization voltage line delivering an anode initialization voltage and an eighth transistor, which is electrically connected between the first node and a bias voltage line delivering a bias voltage. The first node is electrically connected to a first electrode of the first transistor. The second node is electrically connected to a second electrode of the first transistor. The third node is electrically connected to a gate electrode of the first transistor. The fourth node is electrically connected to one of the light-emitting elements.

According to an embodiment, there is provided a display device which includes a substrate having a display area in which emission areas are arranged, and a non-emission area, which is disposed around the display area, a circuit layer disposed on the substrate and an element layer disposed on the circuit layer and including light-emitting elements, which are disposed in the emission areas, respectively. The circuit layer includes emissive pixel driving units, which are electrically connected to the light-emitting elements, and which are arranged to be directed parallel to one another in the first and second directions that intersect each other, data lines, which extend in the second direction and which deliver data signals to the emissive pixel driving units, first auxiliary lines, which extend in the first direction, second auxiliary lines, which extend in the second direction and which are disposed adjacent to the data lines, a first semiconductor layer, which is disposed on the substrate, a first gate insulating layer, which covers the first semiconductor layer, a first gate conductive layer, which is disposed on the first gate insulating layer, a second gate insulating layer, which covers the first gate conductive layer, a second gate conductive layer, which is disposed on the second gate insulating layer, a first interlayer insulating layer, which covers the second conductive layer, a second semiconductor layer, which is disposed on the first interlayer insulating layer, a third gate insulating layer, which covers the second semiconductor layer, a third gate conductive layer, which is disposed on the third gate insulating layer and a second interlayer insulating layer, which covers the third gate conductive layer. The emissive pixel driving units include a first emissive pixel driving unit and a second emissive pixel driving unit, which are disposed adjacent to each other in the second direction, a third emissive pixel driving unit, which is disposed adjacent to the first emissive pixel driving unit in the first direction, a fourth emissive pixel driving unit, which is disposed adjacent to the second emissive pixel driving unit in the first direction, a fifth emissive pixel driving unit, which is disposed adjacent to the second emissive pixel driving unit in the second direction and a sixth emissive pixel driving unit, which is disposed adjacent to the fifth emissive pixel driving unit in the second direction. The first and second semiconductor layers of the first emissive pixel driving unit are arranged to be symmetrical with the first and second semiconductor layers of the second emissive pixel driving unit based on a boundary between the first and second emissive pixel driving units. The first and second semiconductor layers of the first emissive pixel driving unit are arranged to be symmetrical with the first and second semiconductor layers of the third emissive pixel driving unit based on a boundary between the first and third emissive pixel driving units. The first and second semiconductor layers of the second emissive pixel driving unit are arranged to be symmetrical with the first and second semiconductor layers of the fourth emissive pixel driving unit based on a boundary between the second and fourth emissive pixel driving units. The first and second semiconductor layers of the fifth emissive pixel driving unit are arranged to be symmetrical with the first and second semiconductor layers of the sixth emissive pixel driving unit based on a boundary between the fifth and sixth emissive pixel driving units. At least one of the first auxiliary lines is disposed adjacent to the boundary between the first and second emissive pixel driving units. At least one other of the first auxiliary lines is disposed to be adjacent to the boundary between the fifth and sixth emissive pixel driving units.

In an embodiment, one of the first auxiliary lines is disposed to be adjacent to the boundary between the first and second emissive pixel driving units. Another one of the first auxiliary lines is disposed to be adjacent to the boundary between the fifth and sixth emissive pixel driving units.

In an embodiment, the display device further includes a display driving circuit supplying data signals to the data lines. The circuit layer further includes data supply lines, which are disposed in the non-display area and which are electrically connected between the data lines and the display driving circuit. A bypass area on one side of the display area includes a bypass middle area, a first bypass side area, which is arranged to be directed parallel to the bypass middle area in the first direction and contacts the non-display area, and a second bypass side area, which is disposed between the bypass middle area and the first bypass side area. The data supply lines extend to the bypass middle area and the second bypass side area. The data lines include first data lines, which are disposed in the first bypass side area, and second data lines, which are disposed in the second bypass side area. The first auxiliary lines include first bypass auxiliary lines, which are electrically connected to the first data lines, and first transmission auxiliary lines, which are the other first auxiliary lines that are not the first bypass auxiliary lines. The second auxiliary lines include second bypass auxiliary lines, which are electrically connected to the first bypass auxiliary lines and which are disposed to be adjacent to the second data lines, and second transmission auxiliary lines, which are the other second auxiliary lines that are not the second bypass auxiliary lines. The data supply lines include first data supply lines and second data supply lines and deliver data signals to the first data lines and are electrically connected to the first data lines through the first bypass auxiliary lines and the second bypass auxiliary lines. The second data supply lines deliver data signals to the second data lines and are directly electrically connected to the second data lines.

In an embodiment, the emissive pixel driving units further include a seventh emissive pixel driving unit and an eighth emissive pixel driving unit, which are disposed adjacent to each other in the second direction, a ninth emissive pixel driving unit, which is disposed adjacent to the seventh emissive pixel driving unit in the first direction, and a tenth emissive pixel driving unit, which is disposed adjacent to the eighth emissive pixel driving unit in the first direction. Two of the first bypass auxiliary lines among the first auxiliary lines are disposed adjacent to the boundary between the first and second emissive pixel driving units and a boundary between the third and fourth emissive pixel driving units. One first transmission auxiliary line among the first auxiliary lines is disposed adjacent to a boundary between the seventh and eighth emissive pixel driving units and a boundary between the ninth and tenth emissive pixel driving units.

In an embodiment, portions of the two first bypass auxiliary lines are disposed adjacent to a junction among the first, second, third, and fourth emissive pixel driving units and are arranged with a first width. A portion of the one first transmission auxiliary line is disposed adjacent to a junction among the seventh, eighth, ninth, and tenth emissive pixel driving units and is arranged with a second width greater than the first width.

In an embodiment, the element layer includes anode electrodes, which are disposed in the emission areas, where portions of the two first bypass auxiliary lines overlap with one of the anode electrodes. A portion of the one first transmission auxiliary line overlaps with another one of the anode electrodes.

According to an embodiment, a display device includes a circuit layer and an element layer, which are disposed on a substrate.

In an embodiment, the element layer may include light-emitting elements, which are disposed in emission regions.

In an embodiment, the circuit layer may include emissive pixel driving units, which are electrically connected to the light-emitting elements and which are arranged to be directed parallel to one another in the first and second directions that intersect each other, data lines, which extend in the second direction and deliver data signals to the emissive pixel driving units, first auxiliary lines, which extend in the first direction, second auxiliary lines, which extend in the second direction and are which are disposed adjacent to the data lines and gate initialization voltage lines, which deliver a gate initialization voltage to the emissive pixel driving units.

In an embodiment, the emissive pixel driving units may include a first emissive pixel driving unit and a second emissive pixel driving unit, which are disposed adjacent to each other in the second direction.

In an embodiment, among the gate initialization voltage lines, a first gate initialization voltage line may overlap with the boundary between the first and second emissive pixel driving units.

According to an embodiment, at least a portion of the first emissive pixel driving unit may be arranged to be symmetrical with at least a portion of the second emissive pixel driving unit based on the boundary between the first and second emissive pixel driving units.

According to an embodiment, a portion of at least one of the first auxiliary lines may overlap with the first gate initialization voltage line.

According to an embodiment, the circuit layer may further include a first semiconductor layer, which is disposed on the substrate, a first gate insulating layer, which covers the first semiconductor layer, a first gate conductive layer, which is disposed on the first gate insulating layer, a second gate insulating layer, which covers the first gate conductive layer, a second gate conductive layer, which is disposed on the second gate insulating layer, a first interlayer insulating layer, which covers the second gate conductive layer, a second semiconductor layer, which is disposed on the first interlayer insulating layer, a third gate insulating layer, which covers the second semiconductor layer, a third gate conductive layer, which is disposed on the third gate insulating layer and a second interlayer insulating layer, which covers the third gate conductive layer. The first and second semiconductor layers of the first emissive pixel driving unit may be arranged to be symmetrical with the first and second semiconductor layers of the second emissive pixel driving unit based on the boundary between the first and second emissive pixel driving units.

According to an embodiment, the emissive pixel driving units may further include a third emissive pixel driving unit, which is disposed adjacent to the first emissive pixel driving unit in the first direction and a fourth emissive pixel driving unit, which is disposed adjacent to the second emissive pixel driving unit in the first direction.

According to an embodiment, the emissive pixel driving units may further include a fifth emissive pixel driving unit, which is disposed adjacent to the second emissive pixel driving unit in the second direction and a sixth emissive pixel driving unit, which is disposed adjacent to the fifth emissive pixel driving unit in the second direction. The first and second semiconductor layers of the fifth emissive pixel driving unit may be arranged to be symmetrical with the first and second semiconductor layers of the sixth emissive pixel driving unit based on the boundary between the fifth and sixth emissive pixel driving units.

In an embodiment, among the gate initialization voltage lines, a second gate initialization voltage line may overlap with a boundary between the fifth emissive pixel driving unit and the sixth emissive pixel driving unit.

In an embodiment, the first gate initialization voltage line disposed on the boundary between the first and second emissive pixel driving units can be electrically connected to the first and second emissive pixel driving units.

Moreover, in an embodiment, the second gate initialization voltage line disposed on the boundary between the fifth and sixth emissive pixel driving units can be electrically connected to the fifth and sixth emissive pixel driving units.

In an embodiment, each of the gate initialization voltage lines can be electrically connected to two pixel rows, each formed by emissive pixel driving units arranged to be directed parallel with each other in the first direction. Therefore, the number of gate initialization voltage lines disposed in the display area can be reduced to half of the number of pixel rows, each formed by emissive pixel driving units arranged to be directed parallel in the first direction, thereby achieving high resolution in the display device.

According to an embodiment, a portion of at least one of the first auxiliary lines may be disposed adjacent to the boundary between the first emissive pixel driving unit and the second emissive pixel driving unit, thereby overlapping with the first gate initialization voltage line.

In an embodiment, a portion of at least one of the first auxiliary lines may be disposed adjacent to the boundary between the fifth and sixth emissive pixel driving units, thereby overlapping with the second gate initialization voltage line.

In this manner, according to an embodiment, the first auxiliary lines, like the gate initialization voltage lines, can be arranged one for every two pixel rows, which can reduce the area consumed by the arrangement of the first auxiliary lines. Moreover, since portions of the first auxiliary lines overlap with the gate initialization voltage lines, coupling defects due to signals transmitted through some of the first auxiliary lines can be mitigated.

Therefore, high resolution can be achieved in the display device while also improving the display quality of the display device.

According to an embodiment, the first auxiliary lines may include first bypass auxiliary lines, which are electrically connected to first data lines among the data lines, and first transmission auxiliary lines, which are the other first auxiliary lines that are not the first bypass auxiliary lines.

In an embodiment, the emissive pixel driving units may further include a seventh emissive pixel driving unit and an eighth emissive pixel driving unit, which are disposed adjacent to each other in the second direction, a ninth emissive pixel driving unit, which is disposed adjacent to the seventh emissive pixel driving unit in the first direction and a tenth emissive pixel driving unit, which is disposed adjacent to the eighth emissive pixel driving unit in the first direction.

In an embodiment, among the gate initialization voltage lines, a third gate initialization voltage line may overlap with the boundary between the seventh and eighth emissive pixel driving units.

According to an embodiment, portions of each of two first bypass auxiliary lines among the first auxiliary lines may be disposed adjacent to the junction among the first, second, third, and fourth emissive pixel driving units and may be arranged with a first width.

Additionally, in an embodiment, a portion of one of the first transmission auxiliary lines among the first auxiliary lines may overlap with the third gate initialization voltage line. A portion of the one first transmission auxiliary line may be disposed adjacent to the junction among the seventh, eighth, ninth, and tenth emissive pixel driving units and may be arranged with a second width greater than the first width.

In an embodiment, two first bypass auxiliary lines can be arranged two for every two pixel rows, thereby reducing the bypass path of data signals from the first data lines. Furthermore, the first transmission auxiliary lines can be arranged one for every two pixel rows, including portions with the second width. Consequently, the resistance of the first transmission auxiliary lines can be reduced. Therefore, delays or distortions in the voltage or power delivered through the first transmission auxiliary lines can be mitigated, and the power consumption of the display device can be reduced.

It should be noted that the effects of the invention are not limited to those described above, and other effects of the invention will be apparent from the following description.

### BRIEF DESCRIPTION OF THE DRAWINGS

The above and other aspects and features of the invention will become more apparent by describing in detail embodiments thereof with reference to the attached drawings, in which:

FIG. 1 is a perspective view of a display device, according to an embodiment;

FIG. 2 is a plan view of the display device of FIG. 1, according to an embodiment;

FIG. 3 is a cross-sectional view taken along line A-A′ of FIG. 2, according to an embodiment;

FIG. 4 is a layout view illustrating portion B of FIG. 2, according to an embodiment;

FIG. 5 is an equivalent circuit diagram illustrating an emissive pixel driving unit of FIG. 4, according to an embodiment;

FIG. 6 is a cross-sectional view illustrating first, second, fourth, and sixth transistors and the light-emitting element of FIG. 5, according to an embodiment;

FIG. 7 is a plan view illustrating the substrate of FIG. 3, according to an embodiment;

FIG. 8 is a layout view illustrating the circuit layer of portion C of FIG. 7, according to an embodiment;

FIG. 9 is a cross-sectional view taken along line F-F′ of FIG. 8, according to an embodiment;

FIG. 10 is a layout view illustrating the circuit layer in portion D of FIG. 7, according to an embodiment;

FIG. 11 is a plan view illustrating the lines in the circuit layer in portion E of FIG. 7 that extend in a first direction, according to an embodiment;

FIG. 12 is a plan view illustrating the first and second semiconductor layers of each of the first, second, third, and fourth emissive pixel driving units of FIG. 11, according to an embodiment;

FIG. 13 is a plan view illustrating first auxiliary lines in portion E of FIG. 7, according to an embodiment;

FIG. 14 is a plan view illustrating first auxiliary lines in portion E of FIG. 7, according to an embodiment;

FIG. 15 is a plan view illustrating first auxiliary lines in portion E of FIG. 7, according to an embodiment;

FIG. 16 is a plan view illustrating first auxiliary lines in portion E′ of FIG. 7 according to the embodiment of FIG. 15;

FIG. 17 is a layout view illustrating portion B of FIG. 2, according to an embodiment;

FIG. 18 is a plan view illustrating first auxiliary lines and anode electrodes in portion E of FIG. 7, according to the embodiment of FIG. 17; and

FIG. 19 is a plan view illustrating first auxiliary lines in portion E′ of FIG. 7, according to the embodiment of FIG. 17.

### DETAILED DESCRIPTION

The invention will now be described more fully hereinafter with reference to the accompanying drawings. The invention may, however, be provided in different forms and embodiments, and should not be construed as limiting. The same reference numbers indicate the same components throughout the disclosure. In the accompanying figures, the thickness of layers and regions may be exaggerated for clarity.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for case of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within about ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, the invention will be described with reference to embodiments and the accompanying drawings.

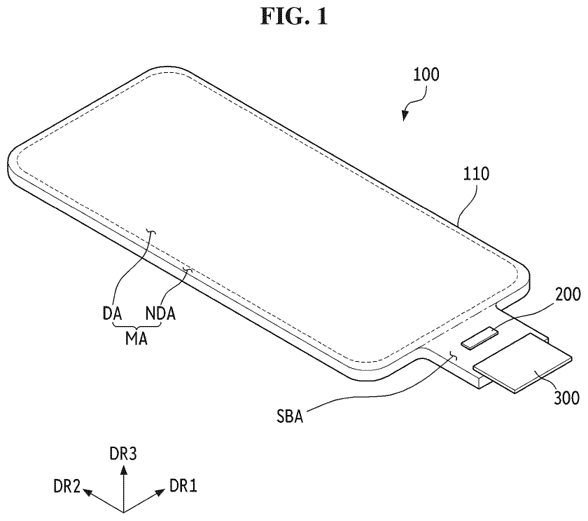

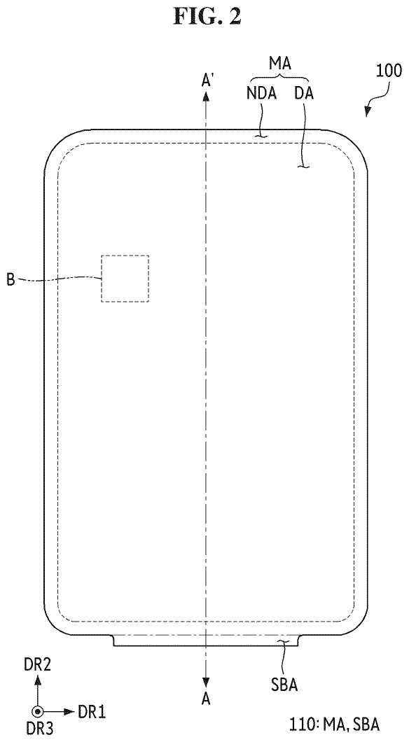

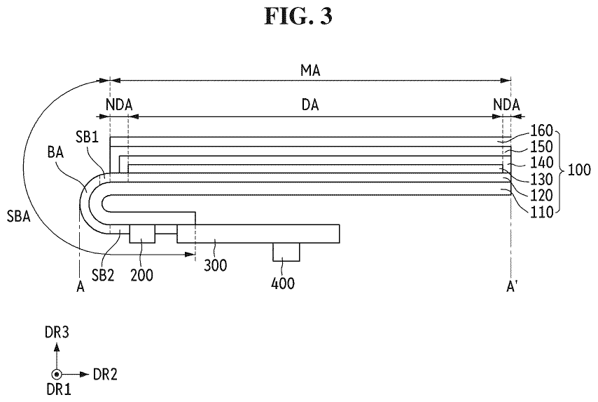

FIG. 1 is a perspective view illustrating a display device, according to an embodiment. FIG. 2 is a plan view illustrating the display device of FIG. 1, according to an embodiment. FIG. 3 is a cross-sectional view taken along line A-A′ of FIG. 2, according to an embodiment.

In an embodiment and referring to FIGS. 1 and 2, a display device 100, which is a device for displaying a moving or still image, may be used as a display screen for various products such as mobile phones, smart phones, tablet personal computers (PC), smart watches, watch phones, portable communication terminals, electronic notepads, electronic books, portable multimedia players (PMPs), navigation devices, and Ultra Mobile PCs (UMPCs), as well as televisions, laptops, monitors, billboards, and Internet of Things (IoT) devices.

In an embodiment, the display device 100 may be a light-emitting display device such as an organic light-emitting display device using organic light-emitting diodes (OLEDs), a quantum dot light-emitting display device including a quantum dot light-emitting layer, an inorganic light-emitting display device including inorganic semiconductors, or a micro- or nano-light-emitting diode (micro- or nano-LED) display device. The display device 100 will hereinafter be described mainly as being an organic light-emitting display device, but the invention is not limited thereto. In another embodiment, the invention may also be applicable to a display device including an organic insulating material, an organic light-emitting material, and a metallic material.

In an embodiment, the display device 100 may be formed flat, but the invention is not limited thereto. For example, the display device 100 may include curved sections at its left and right ends with uniform or varying curvature. Additionally, the display device 100 may be formed to be flexible such as bendable, curvable, foldable, or rollable.

In an embodiment and as illustrated in FIGS. 1, 2, and 3, the display device 100 includes a substrate 110, where the substrate 110 may include a main area MA, which corresponds to the display surface of the display device 100, and a sub-area SBA, which protrudes from one side of the main area MA.

In an embodiment and as illustrated in FIG. 2, the main area MA may include a display area DA, which is disposed in most of the central part of the main area MA, and a non-display area NDA, which is disposed around the display area DA.

The display area DA may be formed as a rectangular plane having short sides in a first direction DR1 and long sides in a second direction DR2, which intersects the first direction DR1. The corners where the short sides in the first direction DR1 meet the long sides in the second direction DR2 may be rounded with a predetermined curvature or may be right-angled. The planar shape of the display area DA is not particularly limited, and the display area DA may be formed in another polygonal shape, a circular shape, or an elliptical shape.

Moreover, the non-display area NDA may be disposed along the edges of the main area MA to surround the display area DA.

The sub-area SBA may be an area extending in the second direction DR2 from a part of one side of the main area MA that extends in the first direction DR1.

The sub-area SBA may include a bending area BA of FIG. 3, which is deformable into a curved shape.

FIGS. 2 and 3 illustrate the display device 100 with a portion of the sub-area SBA bent, according to an embodiment.

In an embodiment and referring to FIG. 3, the sub-area SBA may include the bending area BA, which is deformable into a bent shape, a first sub-area SB1, which is disposed between one side of the main area MA and one side of the bending area BA, and a second sub-area SB2, which extends from the other side of the bending area BA.

When the bending area BA is deformed into a bent shape, the second sub-area SB2 may be disposed on the back of the display device 100 and overlap with the main area MA.

According to an embodiment, a display driving circuit 200, which is implemented as an integrated circuit (IC) chip, may be mounted on the second sub-area SB2.

In an embodiment, a circuit board 300 may be bonded to one side of the second sub-area SB2, and a touch driving circuit 400, which is implemented as an IC chip, may be mounted on the circuit board 300.

In an embodiment and as illustrated in FIG. 3, the display device 100 includes a substrate 110, a circuit layer 120, which is disposed on the substrate 110, and an element layer 130, which is disposed on the circuit layer 120.

According to an embodiment, the display device 100 may further include an encapsulation layer 140, which is disposed on the element layer 130, and a touch sensor layer 150, which is disposed on the encapsulation layer 140.

Additionally, in an embodiment, to reduce the reflection of external light, the display device 100 may further include a polarizing layer 160 disposed on the touch sensor layer 150.

In an embodiment, the substrate 110 may be formed of an insulating material such as a polymer resin. For example, the substrate 110 may be formed of polyimide. Additionally, the substrate 110 may be a flexible substrate that is bendable, foldable, or rollable.

In another embodiment, the substrate 110 may be formed of an insulating material such as glass.

In an embodiment, the substrate 110 may include the main area MA and the sub-area SBA, where the main area MA may include the display area DA and the non-display area NDA.

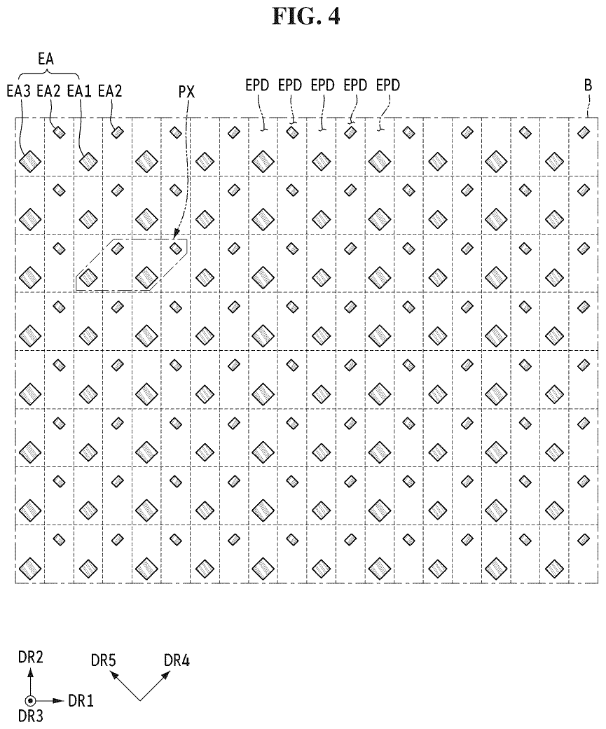

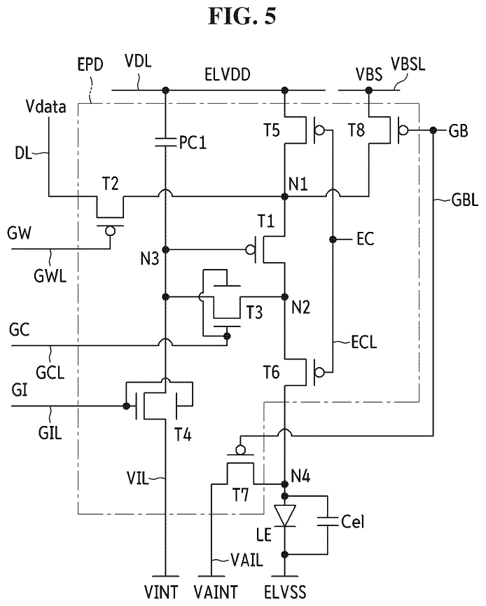

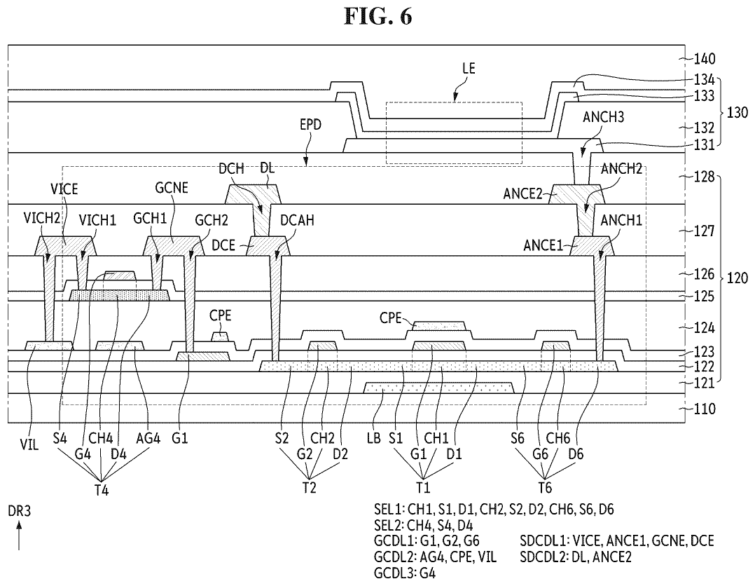

In an embodiment, the element layer 130 may include light-emitting elements LE of FIGS. 5 and 6, which are disposed in emission areas EA of FIG. 4.

In an embodiment, the circuit layer 120 may include emissive pixel driving units EPD, which are electrically connected to the light-emitting elements LE of the element layer 130.

In an embodiment, the encapsulation layer 140, which is disposed on the element layer 130, may have a structure in which at least one organic layer is interposed between two or more inorganic layers.

In an embodiment, the touch sensor layer 150 may include touch electrodes, which are configured to sense a point of touch by a person or an object within the main area MA by detecting signals that vary according to the touch by the person or object.

In an embodiment, the polarizing layer 160 is for preventing a reduction in image visibility caused by the reflection of external light by blocking external light reflected from the touch sensor layer 150, the encapsulation layer 140, the element layer 130, and the circuit layer 120, as well as from their interfaces.

In an embodiment, the display device 100 may further include the display driving circuit 200, which is implemented as an IC chip and which is mounted in the sub-area SBA of the substrate 110. The display driving circuit 200 may supply data signals Vdata to data lines DL of the circuit layer 120.

In an embodiment, the display device 100 may further include the circuit board 300, which is bonded to the sub-area SBA of the substrate 110, where the circuit board 300 may be bonded to pads arranged in the sub-area SBA of the substrate 110 using a low-resistance, high-reliability material such as an anisotropic conductive film or solderable adhesive paste (SAP).

In an embodiment, the touch driving circuit 400 may be mounted on the circuit board 300.

In an embodiment, when the touch sensor layer 150 includes capacitive touch electrodes and sensing electrodes, the touch driving circuit 400 may detect touches based on changes in capacitance, but the invention is not limited thereto. In another embodiment, the touch sensor layer 150 and the touch driving circuit 400 of FIG. 3 may be configured using a touch detection method other than the capacitive method.

FIG. 4 is a layout view illustrating portion B of FIG. 2, according to an embodiment.

In an embodiment and referring to FIG. 4, the display area DA of the display device 100 may include the emission areas EA. Additionally, the display area DA may further include a non-emission area, which is disposed in the spaces between the emission areas EA.

In an embodiment, the emissive pixel driving units EPD, which correspond to the respective emission areas EA, may be arranged in the display area DA and may be directed parallel to one another in the first and second directions DR1 and DR2. The emissive pixel driving units EPD may be electrically connected to the light-emitting elements LE of the element layer 130, which are disposed in the respective emission areas EA.

In an embodiment, the emission areas EA may have a rhombus or rectangular shape on a plane, but the invention is not limited thereto. That is, the emission areas EA may have another polygonal shape such as a square, pentagonal, hexagonal shape, or a circular or elliptical shape including curved edges.

In an embodiment, the emission areas EA may include first emission areas EA1, which emit light of a first color in a predetermined wavelength range, second emission areas EA2, which emit light of a second color in a wavelength range lower than that of the first color, and third emission areas EA3, which emit light of a third color in a wavelength range lower than that of the second color.

For example, the first color may be red in a wavelength range of about 600 nm to about 750 nm, the second color may be green in a wavelength range of about 480 nm to about 560 nm, and the third color may be blue in a wavelength range of about 370 nm to about 460 nm.

In an embodiment, the first emission areas EA1 and the third emission areas EA3 may be alternately arranged in at least one of the first and second directions DR1 and DR2, respectively.

In an embodiment, the second emission areas EA2 may be arranged parallel to one another in at least one of the first and second directions DR1 and DR2, respectively.

Additionally, the second emission areas EA2 may be disposed adjacent to the first emission areas EA1 and the third emission areas EA3 in diagonal directions DR4 and DR5 that intersect the first direction DR1 and the second direction DR2.

In an embodiment, pixels PX that display respective brightness and color may be provided by groups of neighboring emission areas EA, with each group including at least one first emission area EA1, at least one second emission area EA2, and at least one third emission area EA3.

In other words, the pixels PX may be the basic units for displaying various colors, including white, at a predetermined brightness.

In an embodiment, each of the pixels PX may include at least one first emission area EA1, at least one second emission area EA2, and at least one third emission area EA3 that are disposed adjacent to one another. Thus, the pixels PX may display various colors by mixing the light emitted from their respective groups of neighboring emission areas.

FIG. 5 is an equivalent circuit diagram illustrating an emissive pixel driving unit of FIG. 4, according to an embodiment.

In an embodiment and referring to FIG. 5, the circuit layer 120 may include a first power line VDL that delivers a first power supply ELVDD to the emissive pixel driving unit EPD.

A light-emitting element LE may be electrically connected between the emissive pixel driving unit EPD and a second power supply ELVSS.

That is, one light-emitting element LE among the light-emitting elements LE of the element layer 130 may be electrically connected between one emissive pixel driving unit EPD among the emissive pixel driving units EPD of the circuit layer 120 and the second power supply ELVSS.

The second power supply ELVSS may have a voltage level lower than that of the first power supply ELVDD.

That is, an anode electrode of the light-emitting element LE may be electrically connected to the emissive pixel driving unit EPD, and the second power supply ELVSS, which has a voltage level lower than that of the first power supply ELVDD, may be applied to a cathode electrode of the light-emitting element LE.

A capacitor Ce1, which is connected in parallel with the light-emitting element LE, represents the parasitic capacitance between the anode electrode and the cathode electrode of the light-emitting element LE.

The circuit layer 120 may further include the first power line VDL that delivers the first power supply ELVDD, a gate initialization voltage line VIL that delivers a gate initialization voltage VINT, an anode initialization voltage line VAIL that delivers an anode initialization voltage VAINT, and a bias voltage line VBSL that delivers a bias voltage VBS.

The circuit layer 120 may further include a scan write line GWL that delivers a scan write signal GW, a scan initialization line GIL that delivers a scan initialization signal GI, a light emission control line ECL that delivers a light emission control signal EC, a gate control line GCL that delivers a gate control signal GC, and a bias control line GBL that delivers a bias control signal GB.

The emissive pixel driving unit EPD may include a first transistor T1, which generates a driving current for driving the light-emitting element LE, two or more transistors, i.e., transistors T2 through T8, which are electrically connected to the first transistor T1, and at least one capacitor PC1.

The first transistor T1 may be electrically connected between a first node N1 and a second node N2, where the first node N1 is electrically connected to a first electrode (e.g., the source electrode) of the first transistor T1 and the second node N2 is electrically connected to a second electrode (e.g., the drain electrode) of the first transistor T1.

Moreover, the first electrode (e.g., the source electrode) of the first transistor T1 may be electrically connected to the first power line VDL through the fifth transistor T5. Additionally, the second electrode (e.g., the drain electrode) of the first transistor T1 may be electrically connected to the anode electrode of the light-emitting element LE through the sixth transistor T6.

Therefore, the first transistor T1 may be connected in series with the fifth transistor T5, the first transistor T1, the sixth transistor T6 and the light-emitting element LE, while being disposed between the first power supply ELVDD and the second power supply ELVSS.

The pixel capacitor PC1 may be electrically connected between the first power line VDL and a third node N3, where the third node N3 is electrically connected to the gate electrode of the first transistor T1.

That is, the gate electrode of the first transistor T1 may be electrically connected to the first power line VDL through the pixel capacitor PC1.

Thus, the potential of the gate electrode of the first transistor T1 may be maintained by the voltage charged in the first power line VDL.

The second transistor T2 may be electrically connected between a data line DL and the first node N1.

That is, the first electrode of the first transistor T1 may be electrically connected to the data line DL through the second transistor T2.

The second transistor T2 may be turned on by the scan write signal GW from the scan write line GWL.

The fifth transistor T5 may be electrically connected between the first node N1 and the first power line VDL.

The sixth transistor T6 may be electrically connected between the second node N2 and a fourth node N4, where the fourth node N4 is electrically connected to the anode electrode of the light-emitting element LE.

The fifth transistor T5 may be electrically connected between the first electrode of the first transistor T1 and the first power line VDL.

The sixth transistor T6 may be electrically connected between the second electrode of the first transistor T1 and the anode electrode of the light-emitting element LE.

The fifth and sixth transistors T5 and T6 may be turned on by the light emission control signal EC from the light emission control line ECL.

In an embodiment, when a data signal Vdata from the data line DL is delivered to the first electrode of the first transistor T1 through the turned-on second transistor T2, the voltage difference between the gate electrode and the first electrode of the first transistor T1 may become the differential voltage between the first power supply ELVDD and the data signal Vdata.

At this time, if the voltage difference between the gate electrode and the first electrode (i.e., the gate-source voltage) of the first transistor T1 exceeds a threshold voltage, the first transistor T1 may be turned on, generating a drain-source current corresponding to the data signal Vdata through the first transistor T1.

In an embodiment, when the fifth and sixth transistors T5 and T6 are turned on, the first transistor T1 may be connected in series with the light-emitting element LE and disposed between the first power line VDL and the second power line VSL. Accordingly, the drain-source current of the first transistor T1, which corresponds to the data signal Vdata, may be supplied as the driving current for the light-emitting element LE.

As a result, the light-emitting element LE may emit light with a brightness corresponding to the data signal Vdata.

In an embodiment, the third transistor T3 may be electrically connected between the second and third nodes N2 and N3. That is, the third transistor T3 may be electrically connected between the gate electrode and the second electrode of the first transistor T1.

In an embodiment, the third transistor T3 may be turned on by the gate control signal GC from the gate control line GCL.

In an embodiment, the voltage difference between the second and third nodes N2 and N3 may be initialized through the turned-on third transistor T3.

In an embodiment, the fourth transistor T4 may be electrically connected between the gate initialization voltage line VIL and the third node N3. That is, the fourth transistor T4 may be connected between the gate electrode of the first transistor T1 and the gate initialization voltage line VIL.

In an embodiment, the fourth transistor T4 may be turned on by the scan initialization signal GI from the scan initialization line GIL, where the potential of the third node N3 may be initialized through the turned-on fourth transistor T4.

In an embodiment, the third and fourth transistors T3 and T4 may be provided as N-type metal-oxide semiconductor field-effect transistors (MOSFETs).

In an embodiment, the seventh transistor T7 may be electrically connected between the fourth node N4 and the anode initialization voltage line VAIL. That is, the seventh transistor T7 may be electrically connected between the anode electrode of the light-emitting element LE and the anode initialization voltage line VAIL.

In an embodiment, the seventh transistor T7 may be turned on by the bias control signal GB from the bias control line GBL.

In an embodiment, the potential of the fourth node N4 may be initialized through the turned-on seventh transistor T7.

In an embodiment, the eighth transistor T8 may be electrically connected between the first node N1 and the bias voltage line VBSL. That is, the eighth transistor T8 may be electrically connected between the first electrode of the first transistor T1 and the bias voltage line VBSL. The eighth transistor T8 may be turned on by the bias control signal GB from the bias control line GBL and he potential of the first node N1 may be initialized through the turned-on eighth transistor T8.

In an embodiment, among the transistors T1 through T8 included in the emissive pixel driving unit EPD, the transistors T3 and T4 may be provided as N-type MOSFETs, and the other transistors, i.e., the transistors T1, T2, and T5 through T8, may be provided as P-type MOSFETs.

Therefore, according to an embodiment, the circuit layer 120 may include a first semiconductor layer SEL1 for providing the P-type MOSFETs and a second semiconductor layer SEL2 for providing the N-type MOSFETs.

In an embodiment, the first semiconductor layer SEL1 may include the channel portions, the first electrode portions, and the second electrode portions of the P-type MOSFETs (i.e., the transistors T1, T2, T5, T6, and T8).

In an embodiment, the second semiconductor layer SEL2 may include the channel portions, the first electrode portions, and the second electrode portions of the N-type MOSFETs (i.e., the transistors T3, T4, and T7).

In an embodiment, in each of the transistors T1 through T8, the first electrode portion may be connected to one side of the channel portion, and the second electrode portion may be connected to the other side of the channel portion.

In an embodiment, in each of the transistors T1 through T8, the first electrode portion may be a first electrode or source electrode.

In an embodiment, in each of the transistors T1 through T8, the first electrode portion may be a second electrode or drain electrode.

FIG. 6 is a cross-sectional view illustrating the first, second, fourth, and sixth transistors and the light-emitting element of FIG. 5, according to an embodiment.

In an embodiment and referring to FIG. 6, the display device 100 may include the substrate 110, the circuit layer 120 disposed on the substrate 110, and the element layer 130 disposed on the circuit layer 120. The display device 100 may further include the encapsulation layer 140 disposed on the element layer 130.

According to an embodiment, the circuit layer 120 may include a first semiconductor layer SEL1 (CH1, S1, D1, CH2, S2, D2, CH6, S6, and D6), which is disposed on the substrate 110, a first gate insulating layer 122, which covers the first semiconductor layer SEL1, a first gate conductive layer GCDL1 (G1, G2, and G6), which is disposed on the first gate insulating layer 122, a second gate insulating layer 123, which covers the first gate conductive layer GCDL1, a second gate conductive layer GCDL2 (CPE, VIL, and AG4), which is disposed on the second gate insulating layer 123, a first interlayer insulating layer 124, which covers the second gate conductive layer GCDL2, a second semiconductor layer SEL2 (CH4, S4, and D4), which is disposed on the first interlayer insulating layer 124, a third gate insulating layer 125, which covers the second semiconductor layer SEL2, a third gate conductive layer GCDL3 (G4), which is disposed on the third gate insulating layer 125 and a second interlayer insulating layer 126, which covers the third gate conductive layer GCDL3.

According to an embodiment, the circuit layer 120 may further include: a first source/drain conductive layer SDCDL1 (VICE, ANCE1, GCNE and DCE), which is disposed on the second interlayer insulating layer 126, a first planarization layer 127, which covers the first source/drain conductive layer SDCDL1, a second source/drain conductive layer SDCDL2 (DL and ANCE2), which is disposed on the first planarization layer 127 and a second planarization layer 128, which covers the second source/drain conductive layer SDCDL2.

According to an embodiment, the circuit layer 120 may further include a buffer layer 121, which covers the substrate 110. In this case, the first semiconductor layer SEL1 may be disposed on the buffer layer 121 and the buffer layer 121 may cover the light-blocking layer LB on the substrate 110.

In an embodiment, the light-blocking layer LB may overlap with a channel portion CH1 of the first transistor T1.

In an embodiment and as described with reference to FIG. 5, the circuit layer 120 may include the emissive pixel driving unit EPD, which is electrically connected to the light-emitting element LE disposed in the emission area EA, and wiring, which delivers various signals and voltages to the emissive pixel driving unit EPD. The emissive pixel driving unit EPD may include the first transistor T1 and two or more transistors (i.e., the transistors T2 through T8) electrically connected to the first transistor T1.

In an embodiment, the transistors T1, T2, T5, T6, and T8 may be provided as P-type MOSFETs, and the transistors T3, T4, and T7 may be provided as N-type MOSFETs.

In an embodiment, the transistors T1, T2, and T6, which are provided as P-type MOSFETs, may include channel portions CH1, CH2, and CH6, respectively, first electrode portions S1, S2, and S6, respectively, and second electrode portions D1, D2, and D6, respectively, which are all disposed in the first semiconductor layer SEL1, and gate electrodes G1, G2, and G6, respectively, and which overlap with the channel portions CH1, CH2, and CH6.

In an embodiment, the gate electrodes G1, G2, and G6 of the transistors T1, T2, and T6 may be disposed in the first gate conductive layer GCDL1.

In an embodiment, the first electrode portions S1, S2, and S6 may each be connected to one side of the respective channel portions CH1, CH2, and CH6, and the second electrode portions D1, D2, and D6 may each be connected to the other side of the respective channel portions CH1, CH2, and CH6.

In an embodiment, the first electrode portions S1, S2, and S6 and the second electrode portions D1, D2, and D6 may be doped at a higher concentration than the channel portions CH1, CH2, and CH6.

According to an embodiment, the transistors T5 and T8 may be provided as substantially the same P-type MOSFETs as the transistors T1, T2, and T6, and thus, any redundant descriptions thereof will be omitted.

In an embodiment, the first electrode portion S2 of the second transistor T2 may be electrically connected to the data line DL through a data connection electrode DCE.

In an embodiment, the data connection electrode DCE may be disposed in the first source/drain conductive layer SDCDL2 on the second interlayer insulating layer 126 and may be electrically connected to the source portion S2 of the second transistor T2 through a data auxiliary connection hole DCAH. The data auxiliary connection hole DCAH may pass through the second interlayer insulating layer 126, the third gate insulating layer 125, the first interlayer insulating layer 124, the second gate insulating layer 123, and the first gate insulating layer 122.

In an embodiment, the data line DL may be disposed in the second source/drain conductive layer SDCDL2 on the first planarization layer 127 and may be electrically connected to the data connection electrode DCE through the data connection hole DCH that passes through the first planarization layer 127.

In an embodiment, the second electrode portion D2 of the second transistor T2 may be connected to the first electrode portion S1 of the first transistor T1.

In an embodiment, the second electrode portion D1 of the first transistor T1 may be connected to the first electrode portion S6 of the sixth transistor T6.

In an embodiment, the second electrode portion D6 of the sixth transistor T6 may be electrically connected to an anode electrode 131 through a first anode connection electrode ANCE1 and a second anode connection electrode ANCE2.

In an embodiment, the first anode connection electrode ANCE1 may be disposed on the first source drain conductive layer SDCDL1 of the second interlayer insulating layer 126 and may be electrically connected to the second electrode portion D6 of the sixth transistor T6 through a first anode contact hole ANCH1.

In an embodiment, the first anode contact hole ANCH1 may pass through the second interlayer insulating layer 126, the third gate insulating layer 125, the first interlayer insulating layer 124, the second gate insulating layer 123, and the first gate insulating layer 122.

In an embodiment, the second anode connection electrode ANCE2 may be disposed on the second source drain conductive layer SDCDL2 of the first planarization layer 127 and may be electrically connected to the first anode connection electrode ANCE1 through a second anode contact hole ANCH2, which passes through the first planarization layer 127.

In an embodiment, the anode electrode 131 may be disposed on the second planarization layer 128 and may be electrically connected to the second anode connection electrode ANCE2 through a third anode contact hole ANCH3, which passes through the second planarization layer 128.

In an embodiment, the scan write line GWL, which is electrically connected to the gate electrode G2 of the second transistor T2, and the bias control line GBL, which is electrically connected to the gate electrode of the seventh transistor T7, may each be disposed in the first gate conductive layer GCDL1 on the first gate insulating layer 122.

Additionally, in an embodiment, the light emission control line ECL, which is electrically connected to the gate electrode of the fifth transistor T5 and the gate electrode G6 of the sixth transistor T6, may be disposed in the first gate conductive layer GCDL1 or the second gate conductive layer GCDL2.

According to an embodiment, the circuit layer 120 may further include a capacitor electrode CPE, which overlaps with the gate electrode G1 of the first transistor T1, where the capacitor electrode CPE may be disposed in the second gate conductive layer GCDL2 on the second gate insulating layer 123. The capacitor electrode CPE may be electrically connected to the first power line VDL.

Consequently, the pixel capacitor PC1 between the gate electrode G1 of the first transistor T1 and the first power line VDL may be formed by the overlapping area between the gate electrode G1 of the first transistor T1 and the capacitor electrode CPE.

According to an embodiment, the transistors T3, T4, and T7, which are implemented as N-type MOSFETs, may each include an auxiliary gate electrode AG4 disposed in the second gate conductive layer GCDL2 on the second gate insulating layer 123, a channel portion CH4, a first electrode portion S4, and a second electrode portion D4 disposed in the second semiconductor layer SEL2 on the first interlayer insulating layer 124, and a gate electrode G4 disposed in the third gate conductive layer GCDL3 on the third gate insulating layer 125 and overlapping the channel portion CH4.

In an embodiment, the third gate conductive layer GCDL3 may further include the gate control line GCL, which is electrically connected to the gate electrode of the third transistor T3, and the scan initialization line GIL, which is electrically connected to the gate electrode G4 of the fourth transistor T4.

According to an embodiment, the transistors T3 and T7 are implemented as substantially the same N-type MOSFETs as the fourth transistor T4, and thus, redundant descriptions thereof will be omitted.

In an embodiment, the first electrode portion S4 of the fourth transistor T4 may be electrically connected to the gate initialization voltage line VIL through an initialization voltage connection electrode VICE.

In an embodiment, the initialization voltage connection electrode VICE may be disposed in the first source drain conductive layer SDCDL1 on the second interlayer insulating layer 126.

In an embodiment, the initialization voltage connection electrode VICE may be electrically connected to the gate initialization voltage line VIL through a first initialization voltage connection hole VICH1 and to the first electrode portion S4 of the fourth transistor T4 through a second initialization voltage connection hole VICH2.

In an embodiment, the second electrode portion D4 of the fourth transistor T4 may be electrically connected to the gate electrode G1 of the first transistor T1 through the gate connection electrode GCNE, where the gate connection electrode GCNE is disposed in the first source drain conductive layer SDCDL1 on the second interlayer insulating layer 126.

Additionally, the gate connection electrode GCNE may be electrically connected to the second electrode portion D4 of the fourth transistor T4 through a first gate connection hole GCH1 and to the gate electrode G1 of the first transistor T1 through a second gate connection hole GCH2.

In an embodiment, the element layer 130 may be disposed on the circuit layer 120 and may include the light-emitting element LE that corresponds to the emission area EA, where the light-emitting element LE may include the anode electrode 131 and a cathode electrode 134, which face each other, with a light-emitting layer 133 disposed therebetween.

That is, the element layer 130 may include the anode electrode 131, which is disposed in the emission area EA, a pixel-defining layer 132, which is disposed in the non-emission area and covers the edges of the anode electrode 131, the light-emitting layer 133, which is disposed on the anode electrode 131, and the cathode electrode 134, which is disposed on the light-emitting layer 133 and the pixel-defining layer 132.

In another embodiment, the light-emitting element LE may further include a first common layer, which is disposed between the anode electrode 131 and the light-emitting layer 133, and a second common layer, which is disposed between the light-emitting layer 133 and the cathode electrode 134.

In an embodiment, the anode electrode 131 is disposed in the emission area EA and may be electrically connected to the emissive pixel driving unit EPD in the circuit layer 120. The anode electrode 131 may also be referred to as a pixel electrode, where the anode electrode 131 may be electrically connected to the second anode connection electrode ANCE2 through the third anode contact hole ANCH3, which penetrates the second planarization layer 128.

In an embodiment, the light-emitting layer 133 may include an organic light-emitting material that converts electron-hole pairs into light.

In an embodiment, the cathode electrode 134 may be disposed in the display area DA, which includes the emission area EA. The second power supply ELVSS may be commonly applied to the cathode electrode 134. The cathode electrode 134 may also be referred to as a common electrode.

In an embodiment, the encapsulation layer 140 may be disposed on the circuit layer 120 and may cover the element layer 130. For example, the encapsulation layer 140 may be disposed on the element layer 130 and may include a first encapsulation layer, which is disposed on the element layer 130 and formed of an inorganic insulating material, a second encapsulation layer, which is disposed on the first encapsulation layer, overlaps with the element layer 130, and is formed of an organic insulating material, and a third encapsulation layer, which is disposed on the first encapsulation layer, covers the second encapsulation layer, and is formed of an inorganic insulating material.

According to an embodiment, as the emissive pixel driving unit EPD includes transistors T1 through T8 which overlap with the wiring electrically connected thereto, there may be a limit in reducing the width of the emissive pixel driving unit EPD. This may limit the achievement of high resolution in the display device 100.

To address this, the following embodiments provide a display device 100 that can reduce the number of wires disposed in the display area DA while maintaining the number of transistors (T1 through T8) in each emissive pixel driving unit EPD.

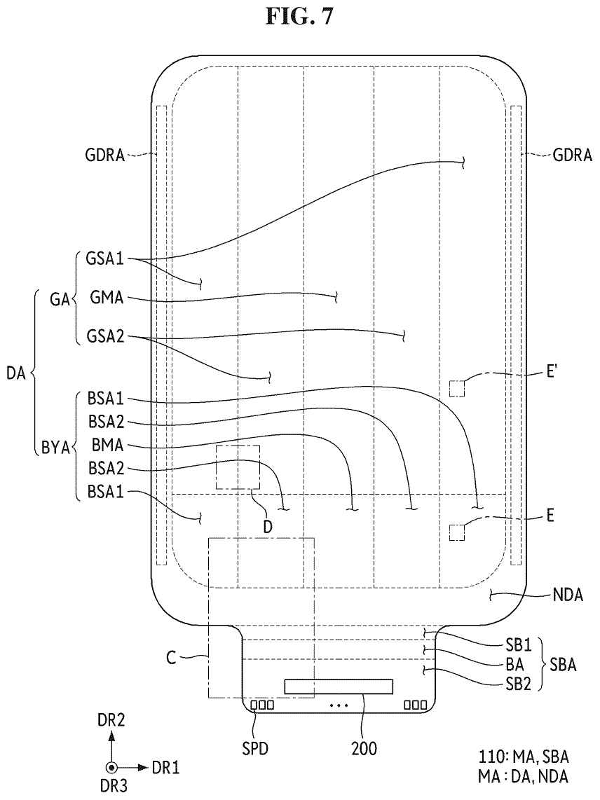

FIG. 7 is a plan view illustrating the substrate of FIG. 3, according to an embodiment.

In an embodiment and referring to FIG. 7, the substrate 110 of the display device 100 includes the main area MA, which corresponds to the display surface, and the sub-area SBA, which protrudes from a part of one side of the main area MA.

The main area MA includes the display area DA, which occupies most of the central part of the main area MA, and the non-display area NDA, which is disposed along the edges of the display area DA and which surrounds the display area DA.

The display area DA may include a bypass area BYA, which is disposed on one side of the display area DA to be located adjacent to the sub-area SBA, and a general area GA, which is disposed in the entire display area DA except for the bypass area BYA.

In an embodiment, the bypass area BYA may include a bypass middle area BMA, which is disposed at the center of the bypass area BYA in the first direction DR1, a first bypass side area BSA1, which is directed parallel to the bypass middle area BMA in the first direction DR1 and which adjoins the non-display area NDA, and a second bypass side area BSA2, which is disposed between the bypass middle area BMA and the first bypass side area BSA1.

The first bypass side area BSA1 may be disposed adjacent to the bent edge of the substrate 110 compared to the bypass middle area BMA and the second bypass side area BSA2.

The first and second bypass side areas BSA1 and BSA2 may be disposed between the bypass middle area BMA and the non-display area NDA.

In an embodiment, the general area GA may include a general middle area GMA, which extends from the bypass middle area BMA of the bypass area BYA in the second direction DR2, a first general side area GSA1, which extends from the first bypass side area BSA1 of the bypass area BYA in the second direction DR2, and a second general side area GSA2, which extends from the second bypass side area BSA2 of the bypass area BYA in the second direction DR2.

In an embodiment, the non-display area NDA may include a gate driving circuit area GDRA, where a gate driving circuit is disposed. The gate driving circuit area GDRA may face one side of the display area DA that extends in the second direction DR2 within the non-display area NDA.

In an embodiment, the gate driving circuit in the gate driving circuit area GDRA may sequentially transmit gate signals to gate lines. Here, the gate lines may include scan write lines GWL that transmit scan write signals GW, scan initialization lines GIL that transmit scan initialization signals GI, gate control lines GCL that transmit gate control signals GC, bias control lines GBL that transmit bias control signals GB, and light emission control lines ECL that transmit light emission control signals EC.

In an embodiment, the sub-area SBA may include the bending area BA, which is deformed into a bent shape, the first sub-area SB1, which is disposed between one side of the bending area BA and the main area MA, and the second sub-area SB2, which is connected to the other side of the bending area BA.

In an embodiment, when the bending area BA is deformed into a bent shape, the second sub-area SB2 is disposed below the substrate 110 and overlaps with the main area MA.

In an embodiment, the display driving circuit 200 may be disposed in the second sub-area SB2 and signal pads SPD, which are bonded to the circuit board 300 of FIG. 3, may be arranged at one edge of the second sub-area SB2.

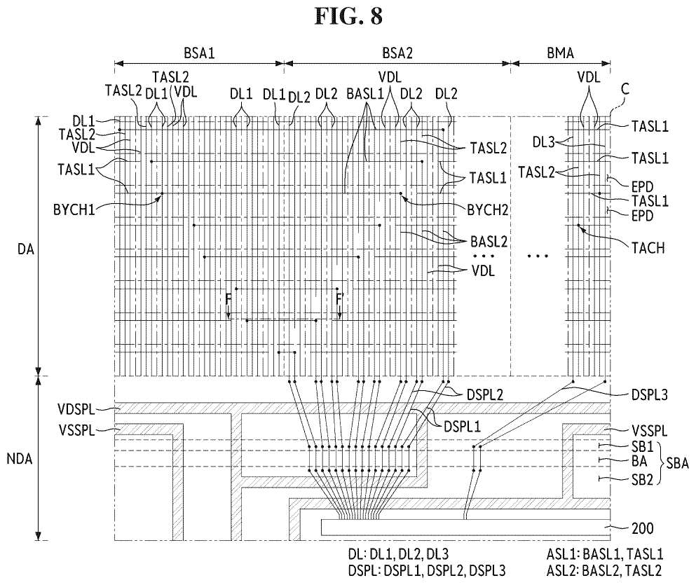

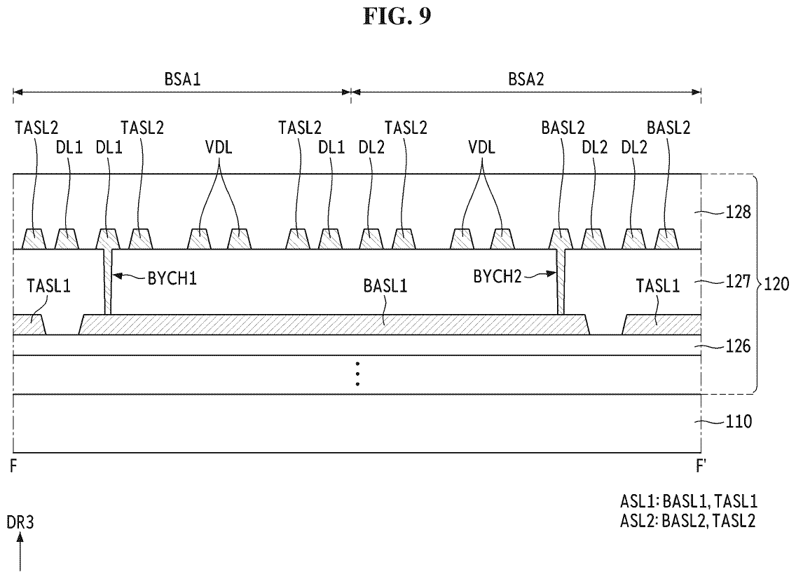

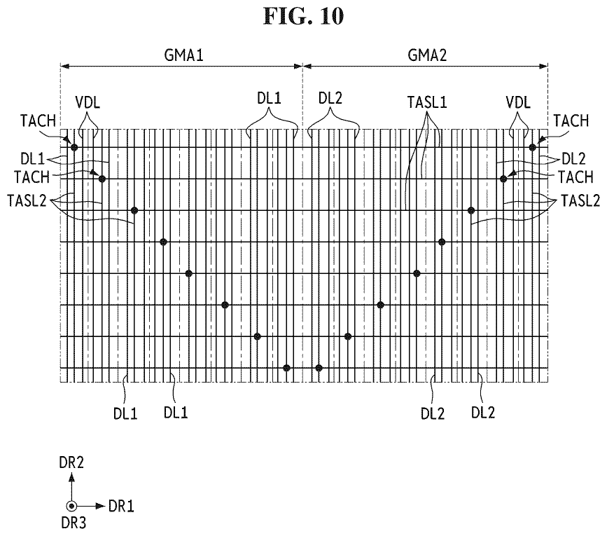

FIG. 8 is a layout view illustrating the circuit layer of portion C of FIG. 7, according to an embodiment. FIG. 9 is a cross-sectional view taken along line F-F′ of FIG. 8, according to an embodiment. FIG. 10 is a layout view illustrating the circuit layer in portion D of FIG. 7, according to an embodiment.

In an embodiment and referring to FIGS. 8 and 10, the circuit layer 120 of the display device 100 may include emissive pixel driving units EPD, which are electrically connected to the light-emitting elements LE of the element layer 130 and which are arranged to be directed parallel to one another in the first direction DR1 and the second direction DR2, data lines DL, which extend in the second direction DR2 and which deliver data signals Vdata to the emissive pixel driving units EPD, first auxiliary lines ASL1, which extend in the first direction DR1, and second auxiliary lines ASL2, which extend in the second direction DR2 and are disposed adjacent to the data lines DL.

In an embodiment, the first auxiliary lines ASL1 may include first bypass auxiliary lines BASL1, which are electrically connected to first data lines DL1 that are data lines DL disposed adjacent to the non-display area NDA in the first direction DR1, and first transfer auxiliary lines TASL1, which account for the other first auxiliary lines ASL1.

In an embodiment, the second auxiliary lines ASL2 may include second bypass auxiliary lines BASL2, which are electrically connected to the first bypass auxiliary lines BASL1 and which are disposed adjacent to second data lines DL2 that are data lines DL spaced farther from the non-display area NDA in the first direction DR1 than the first data lines DL1, and second transfer auxiliary lines TASL2, which account for the other second auxiliary lines ASL2.

In an embodiment, the first bypass auxiliary lines BASL1 may be disposed in the bypass side areas BSA1 and BSA2 of the bypass area BYA and the second bypass auxiliary lines BASL2 may be disposed in the second bypass side area BSA2 of the bypass area BYA.

In an embodiment, at least some of the first transfer auxiliary lines TASL1 and at least some of the second transfer auxiliary lines TASL2 may deliver the second power supply ELVSS of FIG. 5.

In an embodiment, the data lines DL may include the first data lines DL1, which are disposed in the first bypass side area BSA1, and the second data lines DL2, which are disposed in the second bypass side area BSA2.

According to an embodiment, the circuit layer 120 may further include data supply lines DSPL, which are disposed in the non-display area NDA and which are electrically connected between the display driving circuit 200 and the data lines DL.

The data supply lines DSPL may extend into the bypass middle area BMA and the second bypass side area BSA2.

In an embodiment, the data supply lines DSPL may include first data supply lines DSPL1, which deliver data signals for the first data lines DL1, and second data supply lines DSPL2, which deliver data signals for the second data lines DL2.

The first data supply lines DSPL1 may extend to the second bypass side area BSA2 and may be electrically connected to the first data lines DL1 through the second bypass auxiliary lines BASL2 and the first bypass auxiliary lines BASL1.

Additionally, the second data supply lines DSPL2 may extend to the second bypass side area BSA2 and may be electrically connected directly to the second data lines DL2.

In an embodiment, since the first data supply lines DSPL1 extend to the second bypass auxiliary lines BASL2 in the second bypass side area BSA2, rather than to the first data lines DL1 in the first bypass side area BSA1, the extension length of the first data supply lines DSPL1 can be shortened. Consequently, the width of the area required for the arrangement of the data supply lines DSPL can be reduced, thus reducing the width of the non-display area NDA.

Additionally, since the data supply lines DSPL are not arranged in some areas of the non-display area NDA that are disposed adjacent to the bent corner of the substrate 110, the width of the non-display area NDA can be further reduced.

In an embodiment, the data lines DL may further include third data lines DL3, which are disposed in the bypass middle area BMA. Furthermore, the data supply lines DSPL may further include third data supply lines DSPL3, which deliver data signals for the third data lines DL3.

The third data supply lines DSPL3 may extend into the bypass middle area BMA and may be electrically connected directly to the third data lines DL3.

In an embodiment, the first bypass auxiliary lines BASL1 may be disposed between the first data lines DL1 and the second bypass auxiliary lines BASL2.

In an embodiment, the second bypass auxiliary lines BASL2 may be disposed between the first data supply lines DSPL1 and the first bypass auxiliary lines BASL1 in the non-display area NDA.

As such, as the first bypass auxiliary lines BASL1 and the second bypass auxiliary lines BASL2 are arranged exclusively in the bypass area BYA, the ends of the first bypass auxiliary lines BASL1 and the ends of the second bypass auxiliary lines BASL2 are arranged in a predetermined order. As a result, the visibility of the first bypass auxiliary lines BASL1 and the second bypass auxiliary lines BASL2 can be improved.

To prevent this, in an embodiment, the first auxiliary lines ASL1 may include not only the first bypass auxiliary lines BASL1 but also the first transfer auxiliary lines TASL1. Additionally, the second auxiliary lines ASL2 may include not only the second bypass auxiliary lines BASL2 but also the second transfer auxiliary lines TASL2.

In an embodiment, two of the first transfer auxiliary lines TASL1 may extend from both ends of the first bypass auxiliary lines BASL1 to the non-display area NDA.

In an embodiment, one of the second transfer auxiliary lines TASL2 may extend from the ends of the second bypass auxiliary lines BASL2 in a direction that is directed away from the sub-area SBA to the non-display area NDA.

In an embodiment, since the second bypass auxiliary lines BASL2 are only disposed in the second bypass side area BSA2, the first data lines DL1 in the first bypass side area BSA1 may generally be disposed adjacent to the second transmission auxiliary lines TASL2.

In an embodiment, the third data lines DL3 in the bypass middle area BMA may generally be disposed adjacent to the second transmission auxiliary lines TASL2.

According to an embodiment, the circuit layer 120 may further include first power supply lines VDSPL and second power supply lines VSSPL, which deliver the first power supply ELVDD and the second power supply ELVSS, respectively, where the first power supply lines VDSPL and the second power supply lines VSSPL may be disposed in the non-emission area NDA and may extend to the sub-area SBA.

In an embodiment, the first power supply lines VDSPL may be electrically connected to first power pads for delivering the first power supply ELVDD of FIG. 5, among the signal pads SPD of FIG. 7, which are disposed in the second sub-area SB2.

In an embodiment, the second power supply lines VSSPL may be electrically connected to second power pads for delivering the second power supply ELVSS of FIG. 5, among the signal pads SPD, which are disposed in the second sub-area SB2.

In an embodiment, at least some of the first transmission auxiliary lines TASL1 may be electrically connected to the second power supply lines VSSPL.

In an embodiment, at least some of the second transmission auxiliary lines TASL2 may be electrically connected to at least some of the first transmission auxiliary lines TASL1 and the second power supply lines VSSPL.

According to an embodiment, the circuit layer 120 may further include first power lines VDL, which deliver the first power supply ELVDD to the emissive pixel driving units EPD.

The first power lines VDL may be electrically connected to the first power supply lines VDSPL and may be disposed between two adjacent second auxiliary lines ASL2 in the first direction DR1.

In an embodiment and referring to FIG. 9, the data lines DL, the second auxiliary lines ASL2, and the first power lines VDL may be disposed on an insulating layer (e.g., the first planarization layer 127) that covers the first auxiliary lines ASL1.

For example, the first auxiliary lines ASL1 may be disposed on the first source-drain conductive layer SDCDL1 of FIG. 6 on the second interlayer insulating layer 126.

The data lines DL, the second auxiliary lines ASL2, and the first power lines VDL may be disposed on the second source-drain conductive layer SDCDL2 of FIG. 6 on the first planarization layer 127.

In an embodiment, the first bypass auxiliary lines BASL1 may be electrically connected to the first data lines DL1 through first bypass contact holes BYCH1 and to the second bypass auxiliary lines BASL2 through second bypass contact holes BYCH2.

In an embodiment, the first bypass contact holes BYCH1 and the second bypass contact holes BYCH2 may each penetrate the first planarization layer 127.

In an embodiment and referring to FIG. 10, the general area GA may include the first transmission auxiliary lines TASL1 among the first auxiliary lines ASL1 and the second transmission auxiliary lines TASL2 among the second auxiliary lines ASL2.

Moreover, at least some of the first transmission auxiliary lines TASL1 and at least some of the second transmission auxiliary lines TASL2 may be electrically connected to each other through transmission auxiliary contact holes TACH.

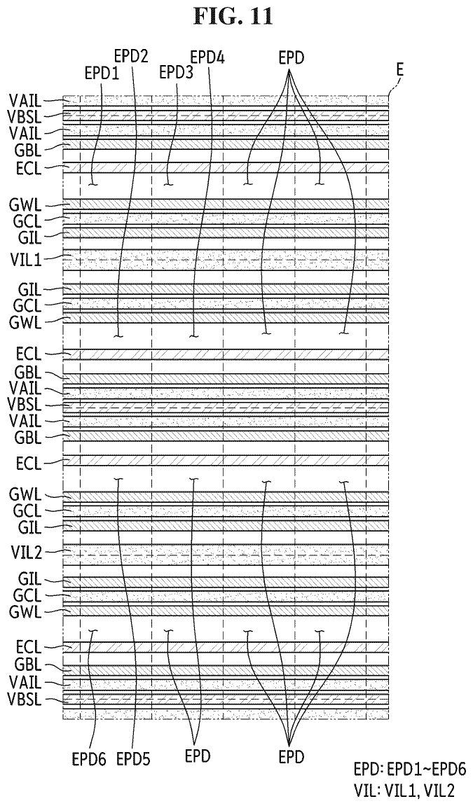

FIG. 11 is a plan view illustrating the lines in the circuit layer in portion E of FIG. 7 that extend in the first direction DR1, according to an embodiment.

FIG. 11 illustrates some of the lines disposed below the second interlayer insulating layer 126 in the circuit layer 120 and extending in the first direction DR1.

In an embodiment and referring to FIG. 11, the emissive pixel driving units EPD of the display device 100 may include a first emissive pixel driving unit EPD1 and a second emissive pixel driving unit EPD2, which are disposed adjacent to each other in the second direction DR2.

According to an embodiment, the emissive pixel driving units EPD may further include a third emissive pixel driving unit EPD3, which is disposed adjacent to the first emissive pixel driving unit EPD1 in the first direction DR1, and a fourth emissive pixel driving unit EPD4, which is disposed adjacent to the second emissive pixel driving unit EPD2 in the first direction DR1.

According to an embodiment, the emissive pixel driving units EPD may further include a fifth emissive pixel driving unit EPD5, which is disposed adjacent to the second emissive pixel driving unit EPD2 in the second direction DR2, and a sixth emissive pixel driving unit EPD6, which is disposed adjacent to the fifth emissive pixel driving unit EPD5 in the second direction DR2.

According to an embodiment, gate initialization voltage lines VIL, anode initialization voltage lines VAIL, bias voltage lines VBSL, and sets of gate lines (GWL, GIL, GCL, ECL, and GBL) that include scan write lines GWL, scan initialization lines GIL, gate control lines GCL, light emission control lines ECL, and bias control lines GBL may be disposed below the second interlayer insulating layer 126 of FIG. 6 and may extend in the first direction DR1.

In an embodiment, the scan write lines GWL, the scan initialization lines GIL, the gate control lines GCL, the light emission control lines ECL, and bias control lines GBL may each be disposed in at least one of the first, second, and third gate conductive layers GCDL1, GCDL2, and GCDL3 of FIG. 6.

In an embodiment, the anode initialization voltage lines VAIL may be disposed in one of the gate conductive layers GCDL1, GCDL2, and GCDL3.

In an embodiment, the gate initialization voltage lines VIL may be disposed in one of the gate conductive layers GCDL1, GCDL2, and GCDL3.

In an embodiment, the bias voltage lines VBSL may be disposed in one of the gate conductive layers GCDL1, GCDL2, and GCDL3.

For example, in an embodiment and as illustrated in FIG. 11, the scan write lines GWL, the scan initialization lines GIL, and the bias control lines GBL may be disposed in the first gate conductive layer GCDL1, the gate initialization voltage lines VIL, the anode initialization voltage lines VAIL, and the gate control lines GCL may be disposed in the second gate conductive layer GCDL2, and the bias voltage lines VBSL and the light emission control lines ECL may be disposed in the third gate conductive layer GCDL3.

However, the illustration in FIG. 11 is merely an example, and the arrangement structure of the sets of gate lines (GWL, GIL, GCL, ECL, and GBL), the gate initialization voltage lines VIL, the anode initialization voltage lines VAIL, and the bias voltage lines VBSL may vary from that depicted in FIG. 11.

Emissive pixel driving units EPD that are arranged to be directed parallel in the first direction DR1 may be classified as a pixel row.

In an embodiment, a set of gate lines (GWL, GIL, GCL, ECL, and GBL), an anode initialization voltage line VAIL, and a bias voltage lines VBSL may be disposed in each pixel row in the display area DA.

According to an embodiment, a first gate initialization voltage line VIL1 among the gate initialization voltage lines VIL may overlap with the boundary between the emissive pixel driving units EPD1 and EPD2.

In an embodiment, the emissive pixel driving units EPD3 and EPD4 are disposed adjacent to the emissive pixel driving units EPD1 and EPD2, respectively, in the first direction DR1. Therefore, the first gate initialization voltage line VIL1 may further overlap with the boundary between the emissive pixel driving units EPD3 and EPD4.

According to an embodiment, a second gate initialization voltage line VIL2 among the gate initialization voltage lines VIL may overlap with the boundary between the emissive pixel driving units EPD5 and EPD6.

That is, the gate initialization voltage lines VIL are disposed not in every pixel row but in every two pixel rows.

To this end, at least a portion of the first emissive pixel driving unit EPD1 may be symmetrical with at least a portion of the second emissive pixel driving unit EPD2, based on the boundary between the emissive pixel driving units EPD1 and EPD2.

Furthermore, in an embodiment, at least a portion of the third emissive pixel driving unit EPD3 may be symmetrical with at least a portion of the fourth emissive pixel driving unit EPD4, based on the boundary between the emissive pixel driving units EPD3 and EPD4.

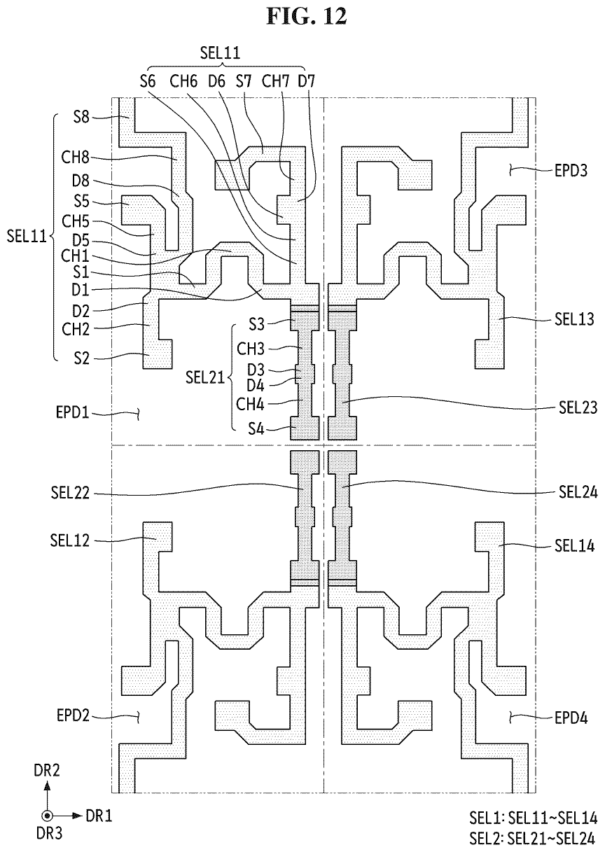

FIG. 12 is a plan view illustrating the first and second semiconductor layers of each of the first, second, third, and fourth emissive pixel driving units EPD of FIG. 11, according to an embodiment.

In an embodiment and referring to FIG. 12, in each emissive pixel driving unit EPD, the first semiconductor layer SEL1 may include the channel portion CH1 of the first transistor T1 of FIG. 5, the first electrode portion S1 of the first transistor T1, the second electrode portion D1 of the first transistor T1, the channel portion CH2 of the second transistor T2 of FIG. 5, the first electrode portion S2 of the second transistor T2, the second electrode portion D2 of the second transistor T2, the channel portion CH5 of the fifth transistor T5 of FIG. 5, the first electrode portion S5 of the fifth transistor T5, the second electrode portion D5 of the fifth transistor T5, the channel portion CH6 of the sixth transistor T6 of FIG. 5, the first electrode portion S6 of the sixth transistor T6, the second electrode portion D6 of the sixth transistor T6, the channel portion CH7 of the seventh transistor T7 of FIG. 5, the first electrode portion S7 of the seventh transistor T7, the second electrode portion D7 of the seventh transistor T7, the channel portion CH8 of the eighth transistor T8 of FIG. 5, the first electrode portion S8 of the eighth transistor T8, and the second electrode portion D8 of the eighth transistor T8.

In an embodiment, the first electrode portion S1 of the first transistor T1 may be connected to one side of the channel portion CH1 of the first transistor T1.

In an embodiment, the second electrode portion D1 of the first transistor T1 may be connected to the other side of the channel portion CH1 of the first transistor T1.

In an embodiment, the first electrode portion S2 of the second transistor T2 may be connected to one side of the channel portion CH2 of the second transistor T2.

In an embodiment, the second electrode portion D2 of the second transistor T2 may be connected to the other side of the channel portion CH2 of the second transistor T2 and to the first electrode portion S1 of the first transistor T1.

In an embodiment, the first electrode portion S5 of the fifth transistor T5 may be connected to one side of the channel portion CH5 of the fifth transistor T5.

In an embodiment, the second electrode portion D5 of the fifth transistor T5 may be connected to the other side of the channel portion CH5 of the fifth transistor T5 and to the first electrode portion S1 of the first transistor T1.

In an embodiment, the first electrode portion S6 of the sixth transistor T6 may be connected to one side of the channel portion CH6 of the sixth transistor T6 and to the second electrode portion D1 of the first transistor T1.

In an embodiment, the second electrode portion D6 of the sixth transistor T6 may be connected to the other side of the channel portion CH6 of the sixth transistor T6.

In an embodiment, the first electrode portion S7 of the seventh transistor T7 may be connected to one side of the channel portion CH7 of the seventh transistor T7.

In an embodiment, the second electrode portion D7 of the seventh transistor T7 may be connected to the other side of the channel portion CH7 of the seventh transistor T7 and to the second electrode portion D6 of the sixth transistor T6.

In an embodiment, the first electrode portion S8 of the eighth transistor T8 may be connected to one side of the channel portion CH8 of the eighth transistor T8.

In an embodiment, the second electrode portion D8 of the eighth transistor T8 may be connected to the other side of the channel portion CH8 of the eighth transistor T8 and to the first electrode portion S1 of the first transistor T1.

In an embodiment, in each emissive pixel driving unit EPD, the second semiconductor layer SEL2 may include the channel portion CH3 of the third transistor T3 of FIG. 5, the first electrode portion S3 of the third transistor T3, the second electrode portion D3 of the third transistor T3, the channel portion CH4 of the fourth transistor T4 of FIG. 5, the first electrode portion S4 of the fourth transistor T4, and the second electrode portion D4 of the fourth transistor T4.

In an embodiment, the first electrode portion S3 of the third transistor T3 may be connected to one side of the channel portion CH3 of the third transistor T3 and may be disposed adjacent to the second electrode portion D1 of the first transistor T1.

In an embodiment, the second electrode portion D3 of the third transistor T3 may be connected to the other side of the channel portion CH3 of the third transistor T3.

In an embodiment, the first electrode portion S4 of the fourth transistor T4 may be connected to one side of the channel portion CH4 of the fourth transistor T4.

In an embodiment, the second electrode portion D4 of the fourth transistor T4 may be connected to the other side of the channel portion CH4 of the fourth transistor T4 and to the second electrode portion D3 of the third transistor T3.

According to an embodiment, the semiconductor layers SEL11 and SEL21 of the first emissive pixel driving unit EPD1 may be symmetrical with the semiconductor layers SEL12 and SEL22 of the second emissive pixel driving unit EPD2 based on the boundary between the emissive pixel driving units EPD1 and EPD2.

Similarly, the semiconductor layers SEL13 and SEL23 of the third emissive pixel driving unit EPD3 may be symmetrical with the semiconductor layers SEL14 and SEL24 of the fourth emissive pixel driving unit EPD4 based on the boundary between the emissive pixel driving units EPD3 and EPD4.

In this manner, the second semiconductor layers SEL21, SEL22, SEL23, and SEL24 of the emissive pixel driving units EPD1, EPD2, EPD3, and EPD4 may be disposed adjacent to the junction among the emissive pixel driving units EPD1, EPD2, EPD3, and EPD4.

In one example, in an embodiment, the first electrode portion S4 of the fourth transistor T4 in each of the emissive pixel driving units EPD1, EPD2, EPD3, and EPD4 may be disposed adjacent to the junction among the emissive pixel driving units EPD1, EPD2, EPD3, and EPD4.

Thus, in an embodiment and as illustrated in FIG. 11, even if a single first gate initialization voltage line VIL1 is disposed at the boundary between the emissive pixel driving units EPD1 and EPD2 and at the boundary between the emissive pixel driving units EPD3 and EPD4, it can still be electrically connected to the first electrode portion S4 of the fourth transistor T4 in each of the emissive pixel driving units EPD1, EPD2, EPD3, and EPD4.

Therefore, since the number of gate initialization voltage lines VIL disposed in the display area DA can be reduced to half the number of pixel rows, it can be advantageous for achieving high resolution in the display device 100.

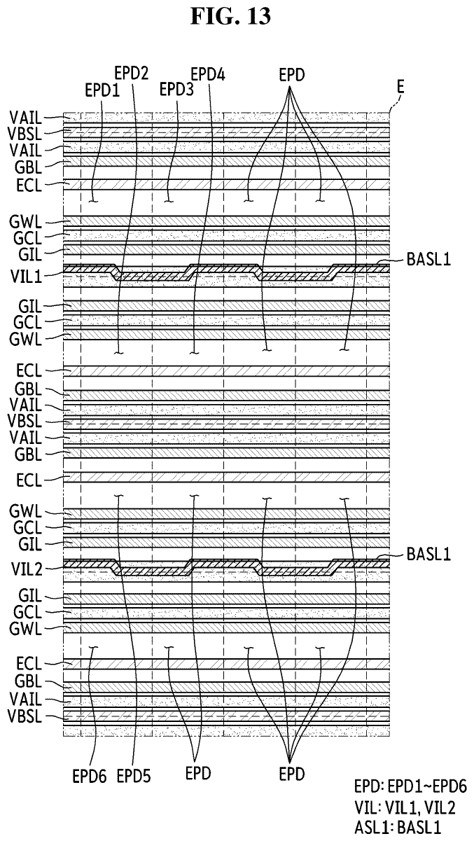

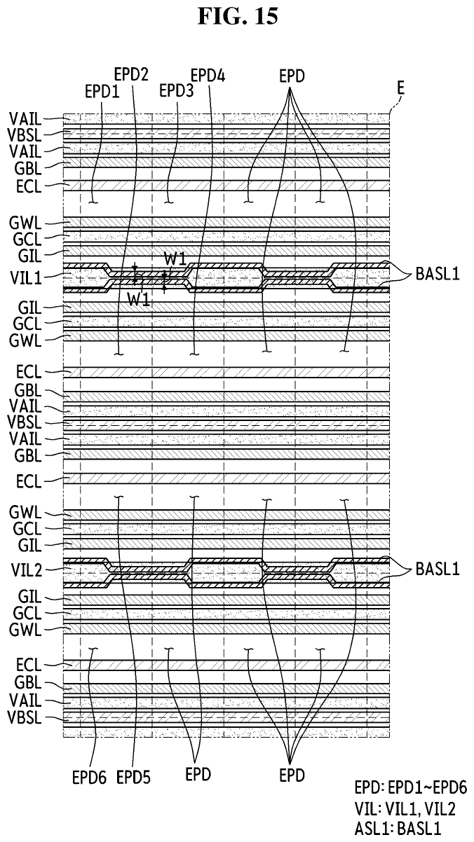

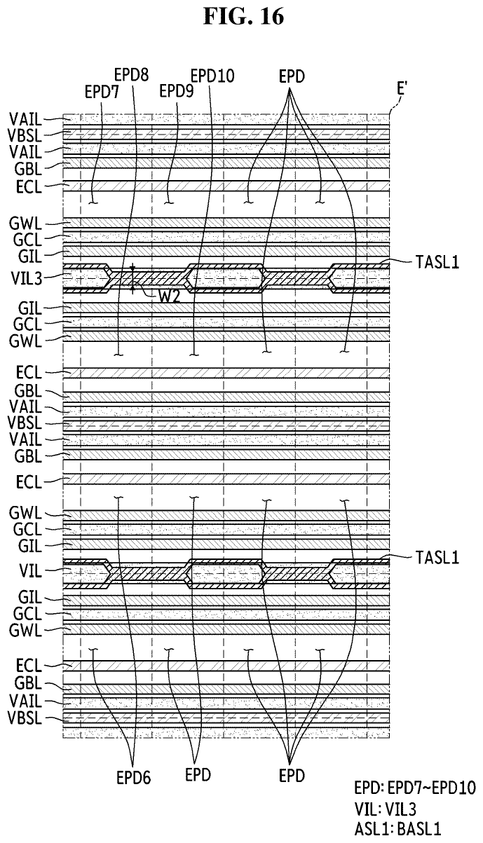

FIGS. 13, 14, and 15 are plan views illustrating first auxiliary lines in portion E of FIG. 7, according to an embodiment. FIG. 16 is a plan view illustrating first auxiliary lines in portion E′ of FIG. 7, according to the embodiment of FIG. 15.

In an embodiment, FIGS. 13, 14, and 15 illustrate first bypass auxiliary lines BASL1, which are disposed in portions of a first bypass side area BSA1 (of FIGS. 7 and 8) and portions of a second bypass side area BSA2 (of FIGS. 7 and 8).

In an embodiment and referring to FIGS. 13, 14, 15, and 16, a portion of at least one of the first bypass auxiliary lines BASL1 among first auxiliary lines ASL1 may overlap with a first gate initialization voltage line VIL1.

According to an embodiment, a portion of at least one other of the first bypass auxiliary lines BASL1 among the first auxiliary lines ASL1 may overlap with a second gate initialization voltage line VIL2.

As illustrated in FIG. 13, according to an embodiment, the first gate initialization voltage line VIL1 may overlap with a portion of one of the first auxiliary lines ASL1 (i.e., a portion of one first bypass auxiliary line BASL1).

In an embodiment, one first auxiliary line ASL1 (i.e., one first bypass auxiliary line BASL1) is disposed adjacent to the boundary between emissive pixel driving units EPD1 and EPD2, and the boundary between emissive pixel driving units EPD3 and EPD4, thereby overlapping with the first gate initialization voltage line VIL1.

According to the embodiment of FIG. 13, the second gate initialization voltage line VIL2 may overlap with a portion of another first bypass auxiliary line BASL1 among the first auxiliary lines ASL1.

In an embodiment, another first bypass auxiliary line BASL1 is disposed adjacent to the boundary between emissive pixel driving units EPD5 and EPD6, thereby overlapping with the second gate initialization voltage line VIL2.

Thus, in the embodiment of FIG. 13, the first auxiliary lines ASL1, like gate initialization voltage lines VIL, may be arranged one for every two pixel rows.

Additionally, in the embodiment of FIG. 13, first transmission auxiliary lines TASL1 (of FIG. 8), like the first bypass auxiliary lines BASL1, may also be arranged one for every two pixel rows and may overlap with the gate initialization voltage lines VIL.

In this manner, the signal coupling defects of the first auxiliary lines ASL1 can be mitigated by a gate initialization voltage VINT (of FIG. 5) from the gate initialization voltage lines VIL. Furthermore, since the number of first auxiliary lines ASL1 disposed in a display area DA can be reduced to half the number of pixel rows, it can be advantageous for achieving high resolution in the display device 100.

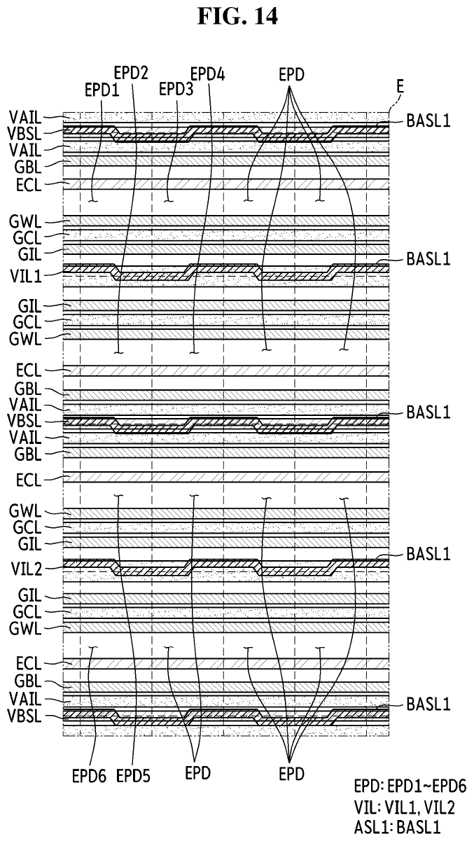

In an embodiment and as illustrated in FIG. 14, one bias voltage line VBSL and one anode initialization voltage line VAIL may be disposed adjacent to the boundary between emissive pixel driving units EPD2 and EPD5.

In the embodiment of FIG. 14, a portion of a first auxiliary lines ASL1 (i.e., one first bypass auxiliary line BASL1) may overlap with a portion of the bias voltage line VBSL or a portion of the anode initialization voltage line VAIL.

That is, the first auxiliary line ASL1 (i.e., one first bypass auxiliary line BASL1) may be disposed adjacent to the boundary between the emissive pixel driving units EPD2 and EPD5, thereby overlapping with the bias voltage line VBSL or the anode initialization voltage line VAIL.

According to the embodiment of FIG. 14, first auxiliary lines ASL1 may be arranged one for every pixel row. Moreover, first transmission auxiliary lines TASL1 (of FIG. 8), like first bypass auxiliary lines BASL1, may also be arranged one for every pixel row and may overlap with gate initialization voltage lines VIL. In another embodiment, the first transmission auxiliary lines TASL1 may overlap with bias voltage lines VBSL or anode initialization voltage lines VAIL.

In this manner, compared to the embodiment of FIG. 13, the length of second transmission auxiliary lines TASL2 can be reduced, and as a result, the distortion of data signals Vdata (of FIG. 8) caused by the second transmission auxiliary lines TASL2 can be mitigated.

In an embodiment and as illustrated in FIG. 15, a first gate initialization voltage line VIL1 may overlap with portions of two first bypass auxiliary lines BASL1 among first auxiliary lines ASL1.

That is, the two first bypass auxiliary lines BASL1 may be disposed adjacent to the boundary between emissive pixel driving units EPD1 and EPD2, and the boundary between emissive pixel driving units EPD3 and EPD4, thereby overlapping with the first gate initialization voltage line VIL1.

According to the embodiment of FIG. 15, a second gate initialization voltage line VIL2 may overlap with portions of another two first bypass auxiliary lines BASL1 among the first auxiliary lines ASL1.

That is, the other two first bypass auxiliary lines BASL1 may be disposed adjacent to the boundary between emissive pixel driving units EPD5 and EPD6, thereby overlapping with the second gate initialization voltage line VIL2.

Thus, according to the embodiment of FIG. 15, the first bypass auxiliary lines BASL1 may be arranged two for every two pixel rows. Moreover, first transmission auxiliary lines TASL1 (of FIG. 8), like the first bypass auxiliary lines BASL1, may also be arranged two for every two pixel rows and may overlap with gate initialization voltage lines VIL.

In this manner, compared to the embodiment of FIG. 13, the length of second transmission auxiliary lines TASL2 can be reduced, and as a result, the distortion of data signals Vdata (of FIG. 8) caused by the second transmission auxiliary lines TASL2 can be mitigated.

In an embodiment, since all the first bypass auxiliary lines BASL1 overlap with the gate initialization voltage lines VIL, the degree of distortion of the data signals Vdata caused by the first bypass auxiliary lines BASL1 can be reduced. Thus, the display quality of the display device 100 can be improved.

FIG. 16 illustrates first transmission auxiliary lines TASL1 among first auxiliary lines ASL1, according to an embodiment.

The first transmission auxiliary lines TASL1 may be disposed on one side of a first bypass side area BSA1 (of FIG. 7) to be disposed adjacent to a non-display area NDA (of FIG. 7), and on one side of a second bypass side area BSA2 (of FIG. 7) to be disposed adjacent to a bypass middle area BMA (of FIG. 7), and in a bypass middle area BMA and a general area GA (of FIG. 7).

According to the embodiment in FIG. 16, emissive pixel driving units EPD may further include a seventh emissive pixel driving unit EPD7 and an eighth emissive pixel driving unit EPD8, which are disposed adjacent to each other in the second direction DR2, a ninth emissive pixel driving unit EPD9, which is disposed adjacent to the seventh emissive pixel driving unit EPD7 in the first direction DR1, and a tenth emissive pixel driving unit EPD10, which is disposed adjacent to the eighth emissive pixel driving unit EPD8 in the first direction DR1.

The embodiment of FIG. 16 is substantially the same as the embodiment of FIG. 15, except that one first transmission auxiliary line TASL1, instead of two, is disposed adjacent to the boundary between the emissive pixel driving units EPD7 and EPD8, and the boundary between the emissive pixel driving units EPD9 and EPD10, and thus, any redundant descriptions will be omitted.

According to the embodiment of FIG. 16, a third gate initialization voltage line VIL3 may overlap with the boundary between the emissive pixel driving units EPD7 and EPD8 and with the boundary between the emissive pixel driving units EPD9 and EPD10.

In an embodiment, a portion of one first transmission auxiliary line TASL1 among first auxiliary lines ASL1 may overlap with the third gate initialization voltage line VIL3.

That is, while in the embodiment of FIG. 15, the first gate initialization voltage line VIL1 overlaps with portions of two first bypass auxiliary lines BASL1, in the embodiment of FIG. 16, the third gate initialization voltage line VIL3 may overlap with a portion of one first transmission auxiliary line TASL1.

As illustrated in FIG. 15, portions of the two first bypass auxiliary lines BASL1 may overlap with the first gate initialization voltage line VIL1 and may be disposed adjacent to the junction among emissive pixel driving units EPD1, EPD2, EPD3, and EPD4. Additionally, portions of the two first bypass auxiliary lines BASL1 may be arranged with a first width W1.

In contrast, in an embodiment and as illustrated in FIG. 16, a portion of one first transmission auxiliary line TASL1 may overlap with the third gate initialization voltage line VIL3 and may be disposed adjacent to the junction among the emissive pixel driving units EPD7, EPD8, EPD9, and EPD10. Furthermore, a portion of one first transmission auxiliary line TASL1 may be arranged with a second width W2, which is greater than the first width W1.

For example, in an embodiment, the second width W2 may be more than twice the first width W1.

In this manner, the resistance of the first transmission auxiliary lines TASL1 can be reduced. Consequently, distortion in the voltage or power (e.g., a second power supply ELVSS of FIG. 5) transmitted through the first transmission auxiliary lines TASL1 can be mitigated. Additionally, since a voltage drop caused by wiring resistance can be reduced, the power consumption of the display device 100 can be decreased.

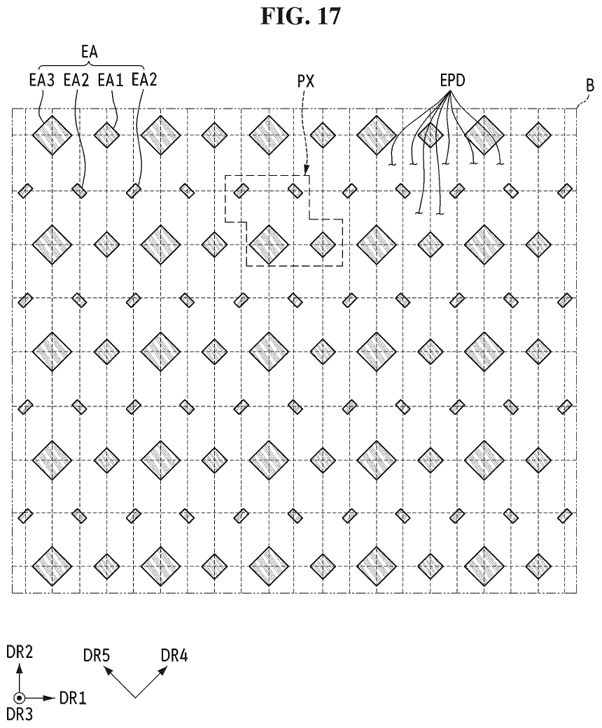

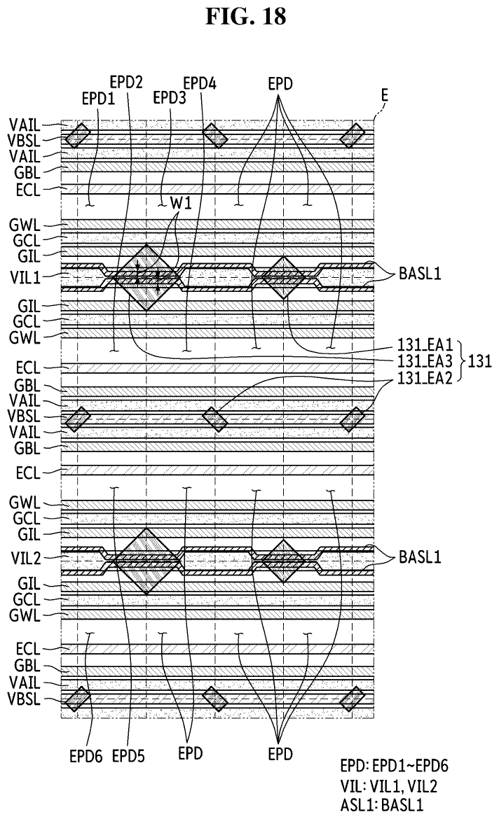

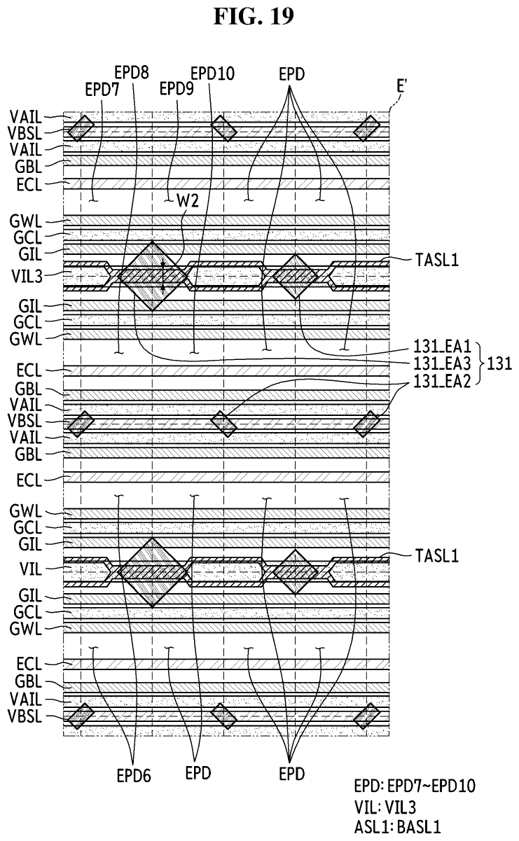

FIG. 17 is a layout view illustrating portion B of FIG. 2, according to an embodiment. FIG. 18 is a plan view illustrating first auxiliary lines and anode electrodes in portion E of FIG. 7, according to the embodiment of FIG. 17. FIG. 19 is a plan view illustrating first auxiliary lines in portion E′ of FIG. 7, according to the embodiment of FIG. 17.

The embodiment illustrated in FIGS. 17, 18, and 19 is substantially the same as the embodiments of FIG. 15 and FIG. 16, except that portions of two first bypass auxiliary lines BASL1, arranged with a first width W1, overlap with one of anode electrodes 131 of an element layer 130, which are disposed in emission areas EA, and a portion of one first transmission auxiliary line TASL1, arranged with a second width W2, overlaps with another anode electrode 131, and thus, any redundant descriptions will be omitted.

As illustrated in FIG. 17, according to an embodiment, each emission area EA may overlap with the junction where four emissive pixel driving units EPD meet.

Accordingly, as illustrated in FIG. 18, according to an embodiment, portions of two first bypass auxiliary lines BASL1 that are arranged with the first width W1 and that overlap with a first gate initialization voltage line VIL1 may overlap with one of anode electrodes 131_EA1, 131_EA2, and 131_EA3 of emission areas EA1, EA2, and EA3.

For example, the portions of the two first bypass auxiliary lines BASL1 may overlap with the anode electrode 131_EA1 of the first emission area EA1 or the anode electrode 131_EA3 of the third emission area EA3, which has a relatively larger width.

Additionally, as illustrated in FIG. 19 and according to an embodiment, a portion of one first transmission auxiliary line TASL1 that is arranged with the second width W2 and that overlaps with a third gate initialization voltage line VIL3 may overlap with one of anode electrodes 131_EA1, 131_EA2, and 131_EA3 of emission areas EA1, EA2, and EA3.

For example, the portion of the first transmission auxiliary line TASL1 may overlap with the anode electrode 131_EA1 of the first emission area EA1 or the anode electrode 131_EA3 of the third emission area EA3, which has a relatively larger width.

In this manner, since portions of two first bypass auxiliary lines BASL1, arranged with the first width W1, and a portion of one first transmission auxiliary line TASL1, arranged with the second width W2, are shielded by the anode electrodes 131, they are not visible externally. Thus, the deterioration of display quality in the display device 100 can be prevented.

Although embodiments of the invention have been described with reference to the attached drawings, it will be understood by those of ordinary skill in the art that the invention can be embodied in other specific forms without departing from the scope, spirit or essential characteristics of the invention. Therefore, the described embodiments are to be considered in all respects as illustrative and not restrictive. Thus, it will be understood by one of ordinary skill in the art to which the invention belongs that the invention may be implemented in other specific embodiments than those described herein without changing the technical spirit or essential features of the invention. Therefore, it is to be understood that the exemplary embodiments described above are illustrative rather than being restrictive in all aspects. The disclosed embodiments of the invention are used in a generic and descriptive sense only and not for purposes of limitation. Each component specifically shown in the embodiments of the invention can be implemented by modification, and such modifications and differences related to invention should be construed as being included in the scope of the invention. Moreover, the embodiments or parts of the embodiments may be combined in whole or in part without departing from the scope of the invention.

What is claimed is:

1. A display device comprising:
a substrate including a display area where emission areas are arranged, and a non-emission area which is disposed around the display area;
a circuit layer disposed on the substrate; and
an element layer disposed on the circuit layer and including light-emitting elements, which are disposed in the emission regions,
wherein
the circuit layer includes emissive pixel driving units which are electrically connected to the light-emitting elements and which are arranged to be directed parallel to one another in a first direction and a second direction that intersect each other, data lines, which extend in the second direction and which deliver data signals to the emissive pixel driving units, first auxiliary lines which extend in the first direction, second auxiliary lines which extend in the second direction and which are disposed adjacent to the data lines, and gate initialization voltage lines, which deliver a gate initialization voltage to the emissive pixel driving units,
the emissive pixel driving units include a first emissive pixel driving unit and a second emissive pixel driving unit, which are disposed adjacent to each other in the second direction, and
a first gate initialization voltage line among the gate initialization voltage lines which overlaps with a boundary between the first and second emissive pixel driving units, wherein
at least a portion of the first emissive pixel driving unit is symmetrical with at least a portion of the second emissive pixel driving unit based on the boundary between the first and second emissive pixel driving units, and
a portion of at least one of the first auxiliary lines overlaps with the first gate initialization voltage line.

2. The display device of claim 1, wherein
the circuit layer further includes a first semiconductor layer which is disposed on the substrate, a first gate insulating layer which covers the first semiconductor layer, a first gate conductive layer which is disposed on the first gate insulating layer, a second gate insulating layer which covers the first gate conductive layer, a second gate conductive layer which is disposed on the second gate insulating layer, a first interlayer insulating layer which covers the second gate conductive layer, a second semiconductor layer which is disposed on the first interlayer insulating layer, a third gate insulating layer which covers the second semiconductor layer, a third gate conductive layer which is disposed on the third gate insulating layer and a second interlayer insulating layer which covers the third gate conductive layer, wherein
the first and second semiconductor layers of the first emissive pixel driving unit are symmetrical with first and second semiconductor layers of the second emissive pixel driving unit based on the boundary between the first and second emissive pixel driving units.

3. The display device of claim 2, wherein
the emissive pixel driving units further include a third emissive pixel driving unit, which is disposed adjacent to the first emissive pixel driving unit in the first direction and a fourth emissive pixel driving unit, which is disposed adjacent to the second emissive pixel driving unit in the first direction, wherein
the first gate initialization voltage line further overlaps with a boundary between the third and fourth emissive pixel driving units, and
first and second semiconductor layers of the third emissive pixel driving unit are symmetrical with first and second semiconductor layers of the fourth emissive pixel driving unit based on the boundary between the third and fourth emissive pixel driving units.

4. The display device of claim 3, wherein
a portion of the first gate initialization voltage line intersects a junction among the first, second, third, and fourth emissive pixel driving units, and
a portion of at least one of the first auxiliary lines overlaps with a portion of the first gate initialization voltage line.

5. The display device of claim 4, wherein
the emissive pixel driving units further include a fifth emissive pixel driving unit which is disposed adjacent to the second emissive pixel driving unit in the second direction and
a sixth emissive pixel driving unit which is disposed adjacent to the fifth emissive pixel driving unit in the second direction, wherein
a second gate initialization voltage line among the gate initialization voltage lines overlaps with a boundary between the fifth and sixth emissive pixel driving units,
first and second semiconductor layers of the fifth emissive pixel driving unit are symmetrical with first and second semiconductor layers of the sixth emissive pixel driving unit based on the boundary between the fifth and sixth emissive pixel driving units, and
a portion of at least one other of the first auxiliary lines overlaps with the second gate initialization voltage line.

6. The display device of claim 5, wherein
the first gate initialization voltage line overlaps with a portion of one of the first auxiliary lines, and
the second gate initialization voltage line overlaps with a portion of another one of first auxiliary line.

7. The display device of claim 6, wherein
the circuit layer further includes bias voltage lines, which deliver a bias voltage to the emissive pixel driving units, and anode initialization voltage lines, which deliver an anode initialization voltage to the emissive pixel driving units, wherein
one of the bias voltage lines and one of the anode initialization voltage lines are disposed adjacent to a boundary between the second and fifth emissive pixel driving units, and
a portion of another one of the first auxiliary lines overlaps with a portion of the one bias voltage line or a portion of the one anode initialization voltage line.

8. The display device of claim 5, further comprising:
a display driving circuit, which supplies data signals to the data lines,
wherein
the circuit layer further includes data supply lines, which are disposed in the non-emission area and which are electrically connected between the data lines and the display driving circuit,
a bypass area on one side of the display area which includes a bypass middle area, a first bypass side area which is disposed adjacent to the non-emission area and which is parallel to the bypass middle area in the first direction, and a second bypass side area which is disposed between the bypass middle area and the first bypass side area, wherein
the data supply lines extend into the bypass middle area and the second bypass side area,
the data lines include first data lines which are disposed in the first bypass side area, and second data lines which are disposed in the second bypass side area,
the first auxiliary lines include first bypass auxiliary lines which are electrically connected to the first data lines, and first transmission auxiliary lines which are the other first auxiliary lines that are not the first bypass auxiliary lines,
the second auxiliary lines include second bypass auxiliary lines which are electrically connected to the first bypass auxiliary lines and disposed adjacent to the second data lines, and second transmission auxiliary lines which are the other second auxiliary lines that are not the second bypass auxiliary lines, and wherein
the data supply lines include first data supply lines and second data supply lines,
wherein
the first data supply lines deliver data signals to the first data lines and are electrically connected to the first data lines through the first bypass auxiliary lines and the second bypass auxiliary lines, and
the second data supply lines deliver data signals to the second data lines and are directly electrically connected to the second data lines.

9. The display device of claim 8, wherein
the circuit layer further includes a first power supply line which delivers a first power supply to the emissive pixel driving units,
the light-emitting elements are electrically connected between the emissive pixel driving units and a second power supply, and
at least some of the first transmission auxiliary lines and at least some of the second transmission auxiliary lines deliver the second power supply.

10. The display device of claim 8, wherein the first gate initialization voltage line overlaps with portions of two of the first bypass auxiliary lines among the first auxiliary lines.

11. The display device of claim 10, wherein
the emissive pixel driving units further include a seventh emissive pixel driving unit and an eight emissive pixel driving unit, which are disposed adjacent to each other in the second direction, a ninth emissive pixel driving unit, which is disposed adjacent to the seventh emissive pixel driving unit in the first direction and a tenth emissive pixel driving unit, which is disposed adjacent to the eighth emissive pixel driving unit in the first direction,
a third gate initialization voltage line among the gate initialization voltage lines overlaps with a boundary between seventh and eighth emissive pixel driving units and with a boundary between ninth and tenth emissive pixel driving units, and
a portion of one of the first transmission auxiliary lines overlaps with the third gate initialization voltage line.

12. The display device of claim 11, wherein
portions of the two first bypass auxiliary lines are disposed adjacent to the junction among the first, second, third, and fourth emissive pixel driving units and are arranged with a first width, and
a portion of the one first transmission auxiliary line is disposed adjacent to a junction among the seventh, eighth, ninth, and tenth emissive pixel driving units and is arranged with a second width greater than the first width.

13. The display device of claim 12, wherein
the element layer includes anode electrodes which are disposed in the emission areas, a pixel-defining layer which is disposed in the non-emission area between the emission areas and which covers edges of the anode electrodes, light-emitting layers which are disposed on the anode electrodes and a cathode electrode which is disposed on the pixel-defining layer and the light-emitting layers,
portions of the two first bypass auxiliary lines overlap with one of the anode electrodes, and
a portion of the one first transmission auxiliary line overlaps with another one of the anode electrodes.

14. The display device of claim 5, wherein
one of the emissive pixel driving units includes a first transistor which is electrically connected between a first node and a second node, a pixel capacitor which is electrically connected between a third node and a first power supply line delivering the first power supply, a second transistor which is electrically connected between one of the data lines and the first node, a third transistor which is electrically connected between the second and third nodes, a fourth transistor which is electrically connected between one of the gate initialization voltage lines and the third node, a fifth transistor which is electrically connected between the first power supply line and the first node, a sixth transistor which is electrically connected between the second node and a fourth node, a seventh transistor which is electrically connected between the first node and an anode initialization voltage line delivering an anode initialization voltage and an eighth transistor which is electrically connected between the first node and a bias voltage line delivering a bias voltage, wherein
the first node is electrically connected to a first electrode of the first transistor,
the second node is electrically connected to a second electrode of the first transistor,
the third node is electrically connected to a gate electrode of the first transistor, and
the fourth node is electrically connected to one of the light-emitting elements.

15. A electronic device comprising a display device as a display screen,
wherein the display device comprises:
a substrate including a display area where emission areas are arranged, and a non-emission area which is disposed around the display area;
a circuit layer disposed on the substrate; and
an element layer disposed on the circuit layer, and including light-emitting elements which are disposed in the emission areas,
wherein
the circuit layer includes emissive pixel driving units which are electrically connected to the light-emitting elements and which are arranged parallel to one another in first and second directions that intersect each other, data lines which extend in the second direction and which deliver data signals to the emissive pixel driving units, first auxiliary lines which extend in the first direction, second auxiliary lines which extend in the second direction and which are disposed adjacent to the data lines, a first semiconductor layer which is disposed on the substrate, a first gate insulating layer which covers the first semiconductor layer, a first gate conductive layer which is disposed on the first gate insulating layer, a second gate insulating layer which covers the first gate conductive layer, a second gate conductive layer which is disposed on the second gate insulating layer, a first interlayer insulating layer which covers the second conductive layer, a second semiconductor layer which is disposed on the first interlayer insulating layer, a third gate insulating layer which covers the second semiconductor layer, a third gate conductive layer which is disposed on the third gate insulating layer and a second interlayer insulating layer which covers the third gate conductive layer, wherein
the emissive pixel driving units include a first emissive pixel driving unit and a second emissive pixel driving unit, which are disposed adjacent to each other in the second direction, a third emissive pixel driving unit which is disposed adjacent to the first emissive pixel driving unit in the first direction, a fourth emissive pixel driving unit, which is disposed adjacent to the second emissive pixel driving unit in the first direction, a fifth emissive pixel driving unit which is disposed adjacent to the second emissive pixel driving unit in the second direction and a sixth emissive pixel driving unit which is disposed adjacent to the fifth emissive pixel driving unit in the second direction, wherein
first and second semiconductor layers of the first emissive pixel driving unit are symmetrical with first and second semiconductor layers of the second emissive pixel driving unit based on a boundary between the first and second emissive pixel driving units,
the first and second semiconductor layers of the first emissive pixel driving unit are symmetrical with first and second semiconductor layers of the third emissive pixel driving unit based on a boundary between the first and third emissive pixel driving units,
the first and second semiconductor layers of the second emissive pixel driving unit are symmetrical with first and second semiconductor layers of the fourth emissive pixel driving unit based on a boundary between the second and fourth emissive pixel driving units,
first and second semiconductor layers of the fifth emissive pixel driving unit are symmetrical with first and second semiconductor layers of the sixth emissive pixel driving unit based on a boundary between the fifth and sixth emissive pixel driving units, wherein
at least one of the first auxiliary lines is disposed adjacent to the boundary between the first and second emissive pixel driving units, and
at least one other of the first auxiliary lines is disposed adjacent to the boundary between the fifth and sixth emissive pixel driving units.

16. The electronic device of claim 15, wherein
one of the first auxiliary lines is disposed adjacent to a boundary between the first and second emissive pixel driving units, and
another one of the first auxiliary lines is disposed adjacent to the boundary between the fifth and sixth emissive pixel driving units.

17. The electronic device of claim 15, wherein the display device further comprises:
a display driving circuit supplying data signals to the data lines,
wherein
the circuit layer further includes data supply lines which are disposed in the non-display area and which are electrically connected between the data lines and the display driving circuit,
a bypass area on one side of the display area includes a bypass middle area, a first bypass side area which is parallel to the bypass middle area in the first direction and which contacts the non-display area, and a second bypass side area, which is disposed between the bypass middle area and the first bypass side area,
the data supply lines extend to the bypass middle area and the second bypass side area,
the data lines include first data lines, which are disposed in the first bypass side area, and second data lines, which are disposed in the second bypass side area,
the first auxiliary lines include first bypass auxiliary lines, which are electrically connected to the first data lines, and first transmission auxiliary lines, which are the other first auxiliary lines that are not the first bypass auxiliary lines,
the second auxiliary lines include second bypass auxiliary lines, which are electrically connected to the first bypass auxiliary lines and which are disposed adjacent to the second data lines, and second transmission auxiliary lines, which are the other second auxiliary lines that are not the second bypass auxiliary lines, and
the data supply lines include first data supply lines and second data supply lines,
wherein
the first data supply lines deliver data signals to the first data lines and are electrically connected to the first data lines through the first bypass auxiliary lines and the second bypass auxiliary lines, and
the second data supply lines deliver data signals to the second data lines and are directly electrically connected to the second data lines.

18. The electronic device of claim 17, wherein
the emissive pixel driving units further include a seventh emissive pixel driving unit and an eighth emissive pixel driving unit, which are disposed adjacent to each other in the second direction, a ninth emissive pixel driving unit, which is disposed adjacent to the seventh emissive pixel driving unit in the first direction, and a tenth emissive pixel driving unit, which is disposed adjacent to the eighth emissive pixel driving unit in the first direction,
two of the first bypass auxiliary lines among the first auxiliary lines are disposed adjacent to the boundary between the first and second emissive pixel driving units and a boundary between the third and fourth emissive pixel driving units, and
one first transmission auxiliary line among the first auxiliary lines is disposed adjacent to a boundary between the seventh and eighth emissive pixel driving units and a boundary between the ninth and tenth emissive pixel driving units.

19. The electronic device of claim 18, wherein:
portions of the two first bypass auxiliary lines are disposed adjacent to a junction among the first, second, third, and fourth emissive pixel driving units and which are arranged with a first width, and
a portion of the one first transmission auxiliary line which is disposed adjacent to a junction among the seventh, eighth, ninth, and tenth emissive pixel driving units and which is arranged with a second width that is greater than the first width.

20. The electronic device of claim 19, wherein
the element layer includes anode electrodes, which are disposed in the emission areas,
portions of the two first bypass auxiliary lines overlap with one of the anode electrodes, and
a portion of the one first transmission auxiliary line overlaps with another one of the anode electrodes.
